(19) United States
(12) Patent Application Publication
(10) Pub. No.: US 2026/0082967 A1
(43) Pub. Date: Mar. 19, 2026

(54) JOINT STRUCTURE, SEMICONDUCTOR DEVICE, MANUFACTURING METHOD OF JOINT STRUCTURE, AND MANUFACTURING METHOD OF SEMICONDUCTOR DEVICE

(71) Applicant: FUJI ELECTRIC CO., LTD., Kawasaki-shi (JP)

(72) Inventors: Akira MOROZUMI, Kawasaki-shi (JP); Hidenao KURIBAYASHI, Kawasaki-shi (JP)

(73) Assignee: FUJI ELECTRIC CO., LTD., Kawasaki-shi (JP)

(21) Appl. No.: 19/281,983

(22) Filed: Jul. 28, 2025

(30) Foreign Application Priority Data
Sep. 13, 2024 (JP) 2024-159302

(51) Int. Cl. H10W 70/685; H01L 23/00; H01L 23/498; H10W 72/00; H10W 72/60; H10W 90/00

(52) U.S. Cl. CPC H10W 70/685; H10W 72/07635; H10W 72/646; H10W 90/764

(57) ABSTRACT

A joint structure includes a first conductor and a second conductor, and a laminated bonding material that is arranged between the first conductor and the second conductor to bond the first conductor to the second conductor. The laminated bonding material includes a first bonding material layer bonded to the first conductor, a second bonding material layer bonded to the second conductor, and an auxiliary conductor plate arranged between the first bonding material layer and the second bonding material layer. The auxiliary conductor plate has a melting point higher than melting points of the first bonding material layer and the second bonding material layer. The second conductor has a laser irradiation mark on a back surface thereof, the back surface being opposite to a front surface of the second conductor that faces the laminated bonding material.

### CROSS-REFERENCE TO RELATED APPLICATIONS

This application is based upon and claims the benefit of priority to Japanese Patent Application No. 2024-159302, filed on Sep. 13, 2024, the entire contents of which are incorporated herein by reference.

### BACKGROUND OF THE INVENTION

### 1. Technical Field

The present invention relates to a joint structure, a semiconductor device, a manufacturing method of a joint structure, and a manufacturing method of a semiconductor device.

### 2. Description of the Related Art

As one of methods of electrically connecting a first conductor and a second conductor in a semiconductor device or the like, there is a method in which a bonding material such as solder provided between the first conductor and the second conductor is melted and bonded with a laser (for example, JP 2004-311539 A and JP 2009-188126 A).

### SUMMARY OF THE INVENTION

If there is a member having low heat resistance around a first conductor or a second conductor when a bonding material between the first conductor and the second conductor is melted, the member having low heat resistance is deteriorated by heat when the bonding material is melted. In addition, when the bonding material is melted by laser irradiation, the entire bonding material is not heated to a uniform temperature, and there is a risk that uniform bonding may not be achieved.

One of the objects of the present invention is to prevent surrounding members having low heat resistance from deteriorating due to heat and to uniformly bond the members, when a bonding material between a first conductor and a second conductor is melted and bonded.

A joint structure according to one aspect includes a first conductor, a second conductor, and a laminated bonding material that is arranged between the first conductor and the second conductor and bonds the first conductor and the second conductor. The laminated bonding material includes a first bonding material layer that is bonded to the first conductor, a second bonding material layer that is bonded to the second conductor, and an auxiliary conductor plate that is arranged between the first bonding material layer and the second bonding material layer and has a higher melting point than the first bonding material layer and the second bonding material layer. The second conductor has a laser irradiation mark on a back surface of a surface facing the auxiliary conductor plate.

According to the above aspect, it is possible to prevent surrounding members having low heat resistance from deteriorating due to heat and to uniformly bond the members when a bonding material between a first conductor and a second conductor is melted and bonded.

### BRIEF DESCRIPTION OF THE DRAWINGS

FIG. 1A is a plan view illustrating a joint structure according to a first embodiment, and FIG. 1B is a cross-sectional view illustrating a cross-sectional configuration taken along an alternate long and short dash line A-A′ in FIG. 1A;

FIGS. 2A and 2B are diagrams illustrating a first manufacturing method of the joint structure according to the first embodiment;

FIGS. 3A and 3B are diagrams illustrating how heat is transferred when a bonding material layer of a laminated bonding material is heated;

FIG. 4 is a diagram illustrating a thickness relationship of each layer of a laminated bonding material;

FIGS. 5A to 5C are tables showing examples of preferable relationships between the thickness of the auxiliary conductor plate and the thickness of the bonding material layer;

FIG. 6 is a table showing other examples of preferable relationships between the thickness of the auxiliary conductor plate and the thickness of the bonding material layer;

FIG. 7 is a cross-sectional view illustrating a second manufacturing method of a joint structure according to the first embodiment;

FIGS. 8A and 8B are cross-sectional views illustrating a third manufacturing method of a joint structure according to the first embodiment;

FIG. 9 is a diagram supplementing a dimensional relationship between a bonded member and a laminated bonding material in the joint structure of the first embodiment;

FIG. 10A is a plan view illustrating a modification of the laminated bonding material according to the first embodiment, and FIG. 10B is a cross-sectional view illustrating a cross-sectional configuration taken along an alternate long and short dash line C-C′ in FIG. 10A;

FIG. 11 is a diagram illustrating a configuration example of a semiconductor device according to a second embodiment;

FIG. 12 is a cross-sectional view illustrating a cross-sectional configuration taken along an alternate long and short dash line D-D′ in FIG. 11;

FIG. 13 is a circuit diagram illustrating an inverter circuit formed in the semiconductor device;

FIG. 14 is a cross-sectional view illustrating a configuration example of a semiconductor device according to a third embodiment; and

FIG. 15 is a cross-sectional view illustrating a configuration example of a semiconductor device according to a fourth embodiment.

### DETAILED DESCRIPTION

Hereinafter, embodiments of the present invention are described in detail with reference to the drawings. An X-axis, a Y-axis, and a Z-axis in the figures to be referred to are illustrated for the purpose of specifying a relationship between planes, directions, and the like of the same components illustrated in different figures. The X-axis, the Y-axis, and the Z-axis are orthogonal to each other and form a right-handed coordinate system. In the following description, a direction parallel to the X-axis is referred to as an X-direction, a direction parallel to the Y-axis is referred to as a Y-direction, and a direction parallel to the Z-axis is referred to as a Z-direction. In addition, when each of the X-direction, the Y-direction, and the Z-direction is associated with a (positive or negative) direction of an arrow of the X-axis, the Y-axis, and the Z-axis illustrated, a “positive side” or a “negative side” is attached.

In the present specification, the Z-direction may be referred to as a vertical direction. In the present specification, expressions “on” and “upper” are intended to be on the positive side in the Z-direction with respect to the reference surface, member, position, and the like, and expressions “below” and “lower” are intended to be on the negative side in the Z-direction with respect to the reference surface, member, position, and the like. For example, when it is described that “a member B is arranged on a member A”, the member B is arranged on the positive side in the Z-direction as viewed from the member A. Also, when the expression “the top surface of the member A” is described, the surface includes a surface that is positioned at the end of the member A on the positive side in the Z-direction and faces the positive side in the Z-direction. These directions and designations of surfaces associated with the directions are merely used for convenience of description. Depending on an attachment posture or the like of the exemplified semiconductor device, a correspondence relationship with each of the directions of the X-axis, the Y-axis, and the Z-axis may change. For example, in the present specification, a surface referred to as a “top surface” may be referred to as a “bottom surface”, a “side surface”, or the like, and the designation of other surfaces may be changed accordingly.

The aspect ratio of each member and the magnitude relationship between members in each figure are merely schematically represented and do not necessarily coincide with the relationship among members in a semiconductor device or the like that is actually manufactured. For convenience of description, it is also assumed that a magnitude relationship among members is exaggeratedly expressed, or an expression is different from an actual outer shape of a member used in a semiconductor device. In addition, some of the cross-sectional views illustrate cross-sectional configurations of structures cut along virtual cutting lines that cannot be accurately illustrated in the figures of structures such as semiconductor devices for convenience of description. Furthermore, some of the cross-sectional views illustrate only a cross-sectional configuration of a part of a structure such as a semiconductor device to which the present invention is applied.

The expressions of “not illustrated” and the like in the present specification mean that components to which the expressions are given or the reference signs and lead lines clearly indicating the components are not illustrated in the figures. For example, a “conductor not illustrated” means both cases where a portion (for example, a figure or a line) representing the conductor is not illustrated in the figure, and where a symbol and a lead wire clearly indicating a portion corresponding to the conductor in the figure are not illustrated in the figure. Which case is intended depends on the context. In addition, underlined reference numerals in the figure indicate the entire components including a plurality of portions distinguished by a plurality of reference numerals.

### First Embodiment: Joint Structure

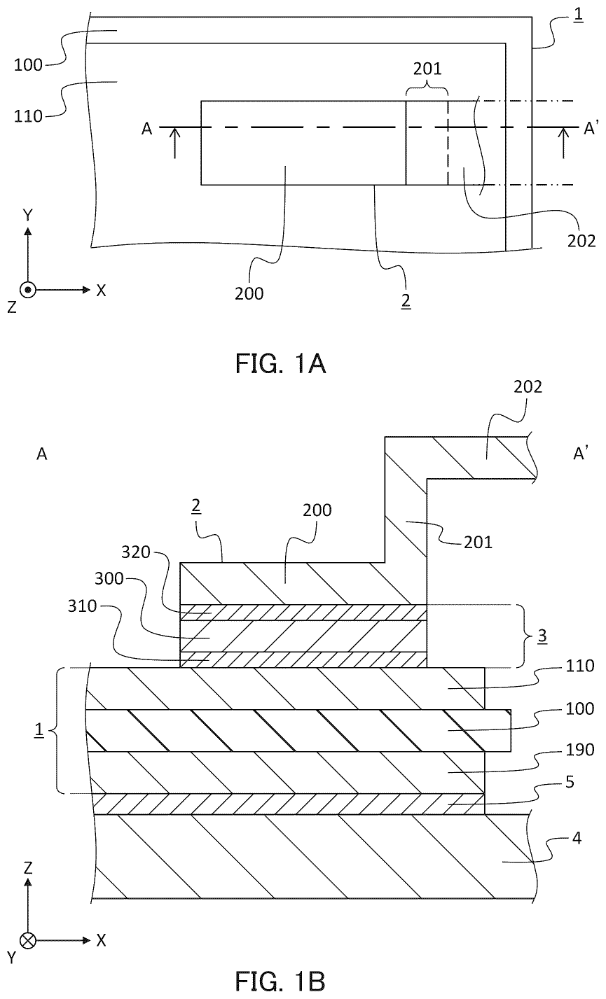

FIG. 1A is a plan view illustrating a joint structure according to a first embodiment, and FIG. 1B is a cross-sectional view illustrating a cross-sectional configuration taken along an alternate long and short dash line A-A′ in FIG. 1A. The expression “joint structure” in the present specification means a structure configured with a plurality of conductors that are bonded members and a laminated bonding material 3 that is inserted between the bonded members and bonded to the bonded members. FIGS. 1A and 1B illustrate a joint structure in which a conductor pattern 110 and a lead terminal 2 are used as bonded members and are bonded to each other with the laminated bonding material 3 interposed therebetween. The laminated bonding material 3 in the illustrated joint structure includes an auxiliary conductor plate 300, a first bonding material layer 310 that is laminated on a bottom surface of the auxiliary conductor plate 300, and a second bonding material layer 320 laminated on a top surface of the auxiliary conductor plate 300.

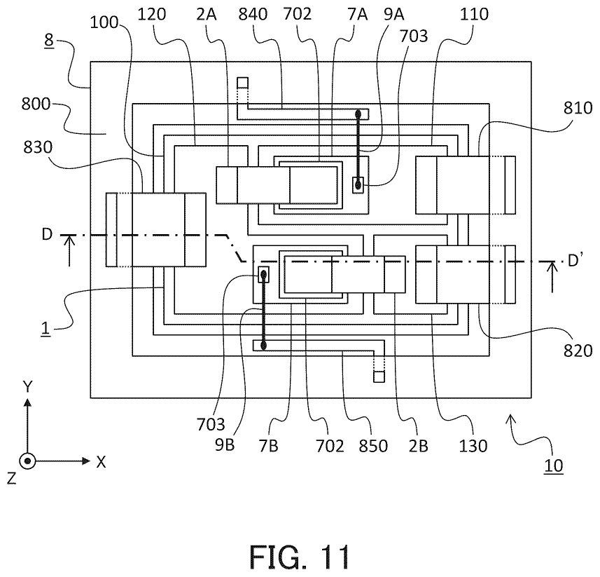

The conductor pattern 110 is a flat plate-shaped bonded member that is laminated on a top surface of an insulating substrate 100 in a wiring board 1 and bonded to the first bonding material layer 310 of the laminated bonding material 3. The lead terminal 2 is one of wiring members and is a bonded member arranged above the conductor pattern 110 via the laminated bonding material 3. The illustrated lead terminal 2 includes a bonded portion 200, a rising portion 201, and a routing portion 202. The bonded portion 200 is a portion that is in contact with the laminated bonding material 3 and is bonded to the second bonding material layer 320 of the laminated bonding material 3. The rising portion 201 is a portion extending in a direction (+Z-direction) opposite to the conductor pattern 110 from an end portion of the bonded portion 200 in a plane parallel to the bottom surface of the bonded portion 200. The routing portion 202 is a portion between an upper end of the rising portion 201 and another bonded portion, a terminal portion, or the like (not illustrated). The shape of the routing portion 202 is not limited to a specific shape. Bondability (for example, joint strength and positioning accuracy) can be improved by using the lead terminal 2 having a bent portion as a connecting portion between the bonded portion 200 and the rising portion 201 and capable of irradiating the bonded portion 200 with laser. Note that the conductor pattern 110 is an example of a first conductor (first bonded member) laminated on an insulating layer, and the lead terminal 2 is an example of a second conductor (second bonded member) electrically connected to the first conductor by the laminated bonding material 3. The joint structure according to the present embodiment is applied to, for example, a semiconductor device described below with reference to FIGS. 11 to 15 and the like. The bonded member in the semiconductor device is not limited to the combination of the conductor pattern 110 and the lead terminal 2 described above. The bonded member in the semiconductor device may be, for example, a combination of the top surface electrode of the semiconductor element and the lead terminal 2. Furthermore, the bonded member in the joint structure according to the present embodiment may be, for example, a combination of an external terminal of the semiconductor device (an outer terminal portion of the lead terminal) and a bus bar or the like connected to the external terminal of the semiconductor device. Furthermore, the application target of the joint structure according to the present embodiment is not limited to the semiconductor device. Note that the conductor pattern 110 may be referred to as the first conductor, and the lead terminal 2 may be referred to as the second conductor.

The wiring board 1 may be a laminate including the insulating substrate 100, the conductor pattern 110 arranged on the top surface of the insulating substrate 100, and a heat dissipation layer 190 arranged on the bottom surface of the insulating substrate 100. A conductor pattern different from the conductor pattern 110 is arranged on the top surface of the insulating substrate 100. The conductor pattern 110 and the heat dissipation layer 190 may be arranged so as to be in contact with the insulating substrate 100 or may be bonded to the insulating substrate 100 via a bonding material such as a brazing material. The wiring board 1 may be a direct copper bonding (DCB) substrate or an active metal brazing (AMB) substrate, but the present invention is not limited thereto. The conductor pattern 110 and the heat dissipation layer 190 may be referred to as circuit conductors.

The insulating substrate 100 may be, for example, a ceramic substrate formed of a ceramic material such as aluminum oxide (Al₂O₃), aluminum nitride (AlN), silicon nitride (Si₃N₄), or a composite material of aluminum oxide (Al₂O₃), and zirconium oxide (ZrO₂). The insulating substrate 100 may be a substrate obtained by molding an insulating resin such as an epoxy resin into a sheet shape, a substrate obtained by impregnating a base material such as a glass fiber with an insulating resin, or a substrate obtained by coating the external surface of a flat plate-shaped metal core with an insulating resin, or the like.

The conductor pattern 110 is a wiring member that electrically connects the lead terminal 2 to an electrode of the semiconductor element arranged on the wiring board 1. The electrode of the semiconductor element electrically connected to the lead terminal 2 via the conductor pattern 110 may be a top surface electrode or a bottom surface electrode and may be, for example, a collector electrode or an emitter electrode of an IGBT (Insulated Gate Bipolar Transistor) element formed on a semiconductor element. The heat dissipation layer 190 is used as a heat dissipation component that conducts heat generated by the semiconductor element arranged on the wiring board 1 to a heat dissipation plate 4. The conductor pattern 110 and the heat dissipation layer 190 are formed, for example, with metal foil made of a conductive metal such as copper (Cu), a copper alloy, aluminum (Al), or an aluminum alloy. The conductor pattern 110 and the heat dissipation layer 190 may be obtained by using the above-described metal foil as a base material and forming a coating film of nickel (Ni) or a nickel alloy on the external surface of the base material, for example, by plating. In other words, the conductor pattern 110 and the heat dissipation layer 190 are not limited to those formed of a single metal material but may have a plurality of layers of separate metal materials. Note that the bonded members that are bonded by the laminated bonding material 3 in the present embodiment are not limited to members formed by using a specific metal material and members having a specific structure. The heat dissipation plate 4 may be a metal plate of copper, aluminum, or the like, and the heat dissipation plate 4 and the heat dissipation layer 190 are bonded by a bonding material 5 such as solder. The heat dissipation plate 4 may be one of a plurality of components that configure a cooler or may be a cooler itself.

As described above, the lead terminal 2 includes the bonded portion 200, the rising portion 201, and the routing portion 202. The lead terminal 2 includes another bonded portion or terminal portion (not illustrated) at the end of the routing portion 202 in FIGS. 1A and 1B extended in the +X-direction. The lead terminal 2 is formed using, for example, a metal plate made of a conductive metal such as copper, a copper alloy, aluminum, or an aluminum alloy. The lead terminal 2 may be obtained by using the above-described metal plate as a base material and forming a coating film of nickel, a nickel alloy, or the like for preventing oxidation on the external surface of the base material. The coating film of nickel, a nickel alloy, or the like can be formed, for example, by film formation in a dry process such as sputtering or film formation in a wet process such as wet plating. The coating film of nickel includes nickel in an amount of 98 wt % or more and may include unavoidable impurities other than nickel. Also, the coating film of the nickel alloy may be formed (deposited) by electroless plating and may include 2 to 15 wt % of phosphorus (P) or boron (B). Note that, when at least one of the first bonding material layer 310 and the second bonding material layer 320 of the laminated bonding material 3 is a layer of a tin (Sn)-based bonding material, the material of the external surface of the bonded member that is bonded to the tin-based bonding material is preferably copper, a copper alloy, nickel, or a nickel alloy that is easily solid-solved with tin and more preferably copper or a copper alloy. Note that the copper alloy is an alloy containing 60% or more of copper, and the nickel alloy is an alloy containing 60% or more of nickel. Also, the base material in the bonded member such as the lead terminal 2 and the conductor pattern 110 may be a conductive member including the above-described metal plate or metal foil and a coating film coating the metal plate or metal foil. In other words, the conductor as the bonded member is also referred to as a base material and may include a coating film. Note that the top surface of the bonded portion 200 of the lead terminal 2 may be irradiated with laser and may have an irradiation mark as a mark thereof as described below.

The laminated bonding material 3 is a bonding member that electrically connects the conductor pattern 110 of the wiring board 1 and the bonded portion 200 of the lead terminal 2 and includes the first bonding material layer 310, the second bonding material layer 320, and the auxiliary conductor plate 300. The laminated bonding material 3 illustrated in FIG. 1B is obtained by laminating the first bonding material layer 310, the auxiliary conductor plate 300, and the second bonding material layer 320 in this order from the top surface of the conductor pattern 110 of the wiring board 1 toward the bonded portion 200 of the lead terminal 2. In other words, in the laminated bonding material 3, the auxiliary conductor plate 300 is arranged between the first bonding material layer 310 and the second bonding material layer 320. The first bonding material layer 310 and the second bonding material layer 320 are conductive layers made of metal having a low melting point that can be used as a bonding material as described below. The auxiliary conductor plate 300 is formed with a conductive metal material having a higher melting point than the first bonding material layer 310 and the second bonding material layer 320. The first bonding material layer 310 is bonded to the conductor pattern 110 and the auxiliary conductor plate 300 of the wiring board 1, and the second bonding material layer 320 is bonded to the bonded portion 200 and the auxiliary conductor plate 300 of the lead terminal 2. The “bonding material layer” in the present specification includes an alloy layer of a material of metal having a low melting point used as a bonding material and a material of an external surface of a bonded member. In other words, the first bonding material layer 310 and the second bonding material layer 320 each are illustrated as a single layer in FIG. 1B. However, after bonding, an alloy layer between the material of the bonded members and the bonding material is actually formed at a bonding interface with the bonded members. For example, an alloy layer between a material of metal having a low melting point used for forming the first bonding material layer 310 and a material of the external surface of the conductor pattern 110 is formed on the bonding interface with the conductor pattern 110 in the first bonding material layer 310.

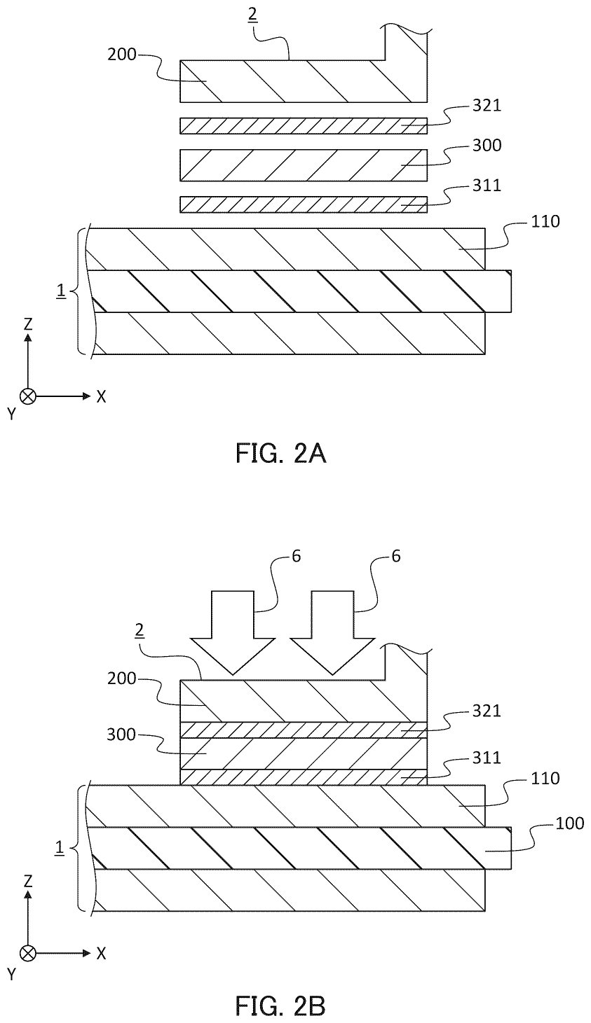

The materials of the first bonding material layer 310 and the second bonding material layer 320 may be selected from metal materials such as brazing materials and solder materials that are melted when the bonded member is irradiated with laser and are capable of being used for bonding with the bonded member. However, when the temperature of the bonded member becomes high due to Joule heat during irradiation with laser, damage to insulating materials near the bonded member, deformation of the bonded member, and the like may occur. For example, the bonding between the conductor pattern 110 and the lead terminal 2 by the laminated bonding material 3 illustrated in FIGS. 1A and 1B is performed by irradiation of the top surface of the bonded portion 200 with laser from the upper portion of the bonded portion 200 of the lead terminal 2 (see FIG. 2B). In this example, when the temperature of the conductor pattern 110 and the insulating substrate 100 (for example, a ceramic substrate or an insulating resin substrate) facing the bottom surface of the conductor pattern 110 becomes high during laser irradiation, the insulating substrate 100 may be damaged, and also deformation of the lead terminal 2 or the like may occur. In addition, when one of the bonded members is the top surface electrode of the semiconductor element, the semiconductor element may be damaged due to the high temperature of the top surface electrode. From such a viewpoint, the material of the first bonding material layer 310 and the second bonding material layer 320 is a conductive metal material having a melting point preferably in the range of 100° C. to 400° C. and more preferably in the range of 100° C. to 300° C., for example, in order to reduce damage to other surrounding members due to an increase in temperature during laser irradiation. Such a metal material is hereinafter referred to as “low melting point metal”. Furthermore, when other members that are present around the bonded member during laser irradiation, such as the insulating substrate 100 that faces the bottom surface of the conductor pattern 110, are members formed using an insulating resin, the low melting point metal used as the material for the first bonding material layer 310 and the second bonding material layer 320 may, for example, have a melting point lower than that of the insulating resin in contact with the bonded member. For example, when the insulating substrate 100 is an epoxy resin substrate, the melting point thereof (heat resistance temperature) is about 260° C. For this reason, when the insulating substrate 100 is an epoxy resin substrate, low melting point metal that is conductive, has a melting point, for example, in the range of 100° C. to 250° C., and bondability to materials of external surfaces of the conductor pattern 110 and the lead terminal 2 of the wiring board 1 (more specifically, the material of the external surface of the bottom surface of the bonded portion 200) may be selected as the materials of the first bonding material layer 310 and the second bonding material layer 320.

When the materials of the external surfaces of the conductor pattern 110 and the lead terminal 2 that are the bonded members are copper (Cu) or nickel (Ni), for example, a lead-free solder, specifically, tin (Sn) or an alloy including tin (hereinafter referred to as a “tin alloy”) may be used for the first bonding material layer 310 and the second bonding material layer 320. Tin includes 99 wt % or more of tin and unavoidable impurities. The tin alloy may be an alloy including 30 wt % or more of tin, such as a tin-copper alloy, a tin-silver (Ag) alloy, a tin-bismuth (Bi) alloy, a tin-antimony (Sb) alloy, or a tin-indium (In) alloy and may include unavoidable impurities. Specific examples of compositions and melting points of tin alloys applicable to the first bonding material layer 310 and the second bonding material layer 320 are shown in Table 1.

TABLE 1
Examples of compositions and melting points of tin alloys

| Composition | Melting point (° C.) |
|---|---|
| Sn—52In | 119 |
| Sn—58Bi | 139 |
| Sn3.5Ag0.5Bi4In | 207~212 |
| Sn—3Ag | 221~222 |
| Sn—0.7Cu | 227~228 |
| Sn—5Sb | 238~241 |

Note that it is preferable to select low melting point metal that is not melted or softened due to heat applicable to those bonding material layers after bonding for the materials of the first bonding material layer 310 and the second bonding material layer 320. When a reliability test (for example, high temperature test) of the semiconductor device to which the laminated bonding material 3 is applied is performed at 150° C., the melting point of the low melting point metal used for the first bonding material layer 310 and the second bonding material layer 320 is preferably 150° C. or higher and more preferably 200° C. or higher. Also, in terms of bonding strength, the material of the first bonding material layer 310 and the second bonding material layer 320 is preferably a tin-silver alloy or a tin-copper alloy. The compositions of the first bonding material layer 310 and the second bonding material layer 320 may be the same or may be different from each other.

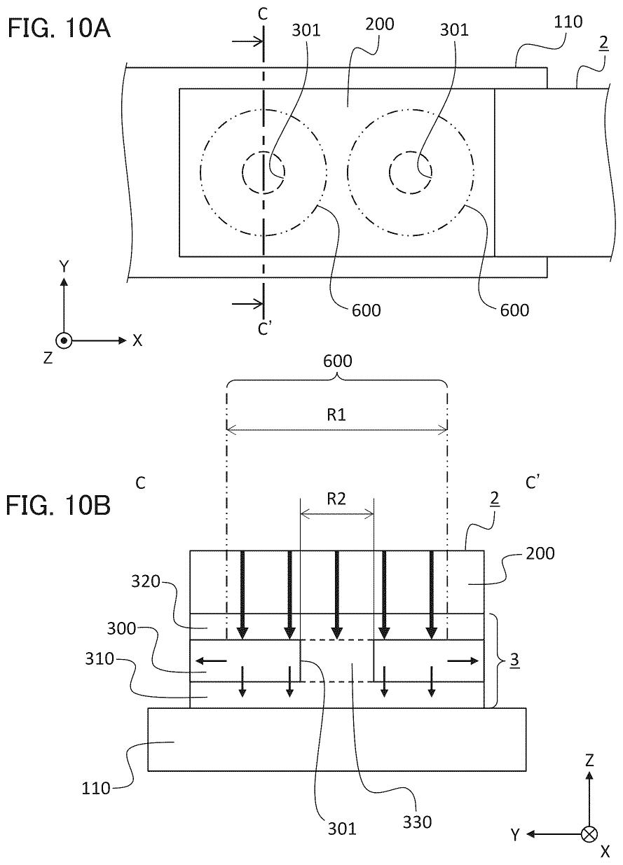

The auxiliary conductor plate 300 is a member that suppresses the direct conduction of heat generated when one bonded member is irradiated with laser to the other bonded member via the bonding material layer to heat the first bonding material layer 310 and the second bonding material layer 320 to a uniform temperature. The auxiliary conductor plate 300 has a higher melting point than the first bonding material layer 310 and the second bonding material layer 320 and is formed of metal or an alloy having a higher melting point than having heat conductivity and electrical conductivity. The shape of the auxiliary conductor plate 300 is preferably a foil or plate shape having a predetermined thickness. The auxiliary conductor plate 300 may include through holes described below with reference to FIGS. 10A and 10B in the range of capable of the direct conduction of heat generated in one bonded member to the other bonded member and capable of heating the first bonding material layer 310 and the second bonding material layer 320 to a uniform temperature. Also, the auxiliary conductor plate 300 is arranged so as to be sandwiched between the first bonding material layer 310 and the second bonding material layer 320, but from the viewpoint of uniformity of heat, the width of the auxiliary conductor plate 300 may be larger. Meanwhile, the width of the auxiliary conductor plate 300 may be smaller, and the first bonding material layer 310 and the second bonding material layer 320 are arranged to be in contact with each other around the auxiliary conductor plate 300. Also, the plurality of foil-shaped or plate-shaped auxiliary conductor plates 300 may be arranged so as to be sandwiched between the first bonding material layer 310 and the second bonding material layer 320.

The material of the auxiliary conductor plate 300 is preferably a material that is conductive, has high heat conductivity, and bondability to the first bonding material layer 310 and the second bonding material layer 320. When the first bonding material layer 310 and the second bonding material layer 320 are tin alloys, for example, any one of copper, a copper alloy, nickel, a nickel alloy, silver, a silver alloy, aluminum, an aluminum alloy, tungsten (W), and molybdenum (Mo) can be selected as the material of the auxiliary conductor plate 300. Also, these materials may also be combined, and for example, the external surface of copper or the like may be coated with a nickel film by plating or the like. At least the external surface of the auxiliary conductor plate is preferably copper, a copper alloy, nickel, or a nickel alloy that is easily solid-soluble with the tin or tin alloy used as the bonding material and more preferably copper or a copper alloy. Note that the materials of the first bonding material layer 310 and the second bonding material layer 320 may be selected based on the material of the auxiliary conductor plate 300.

### (First Manufacturing Method of Joint Structure According to First Embodiment)

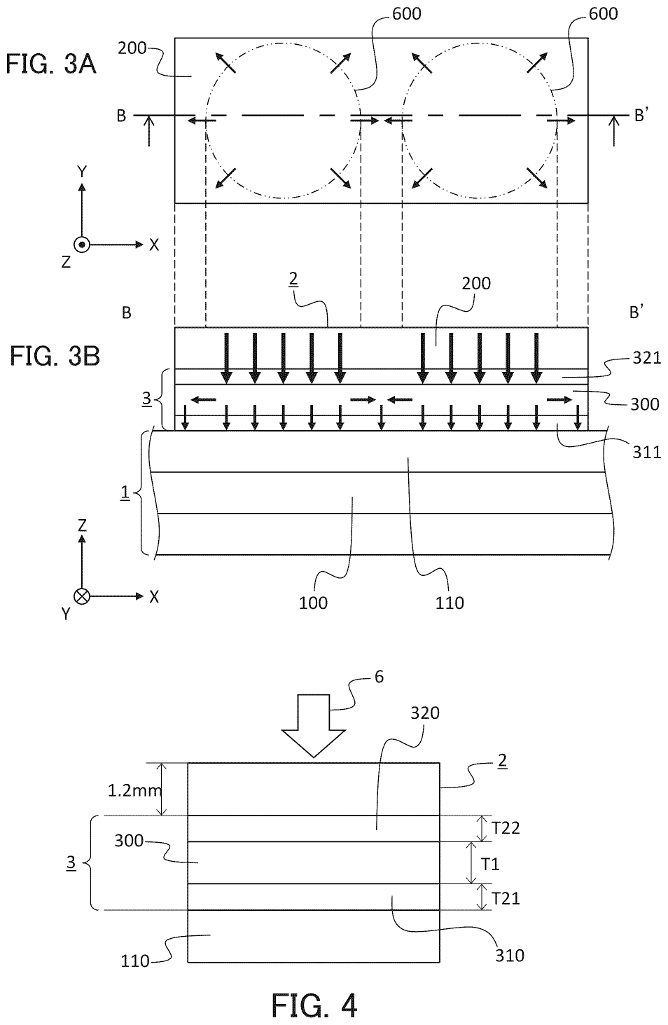

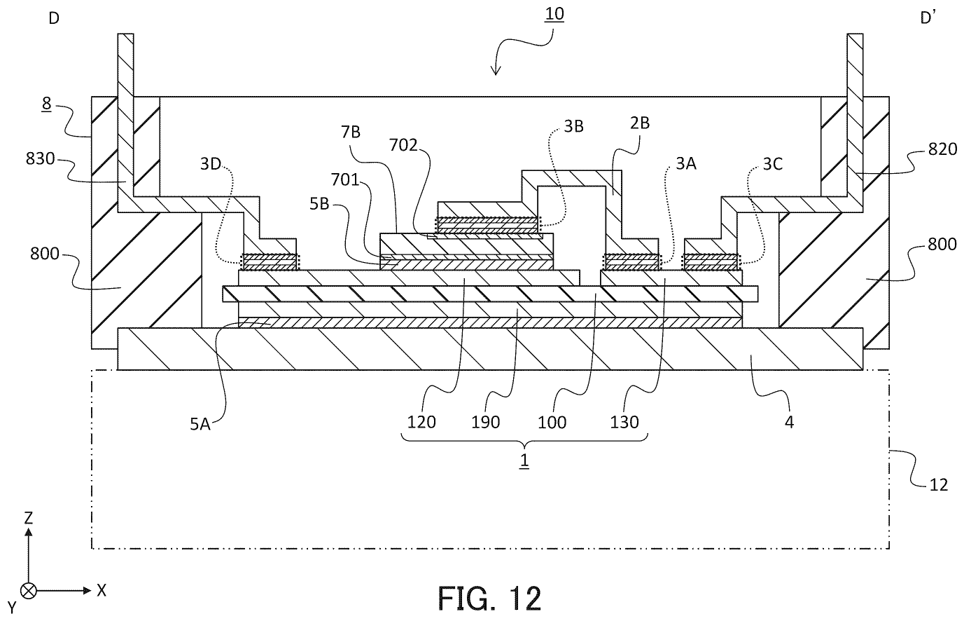

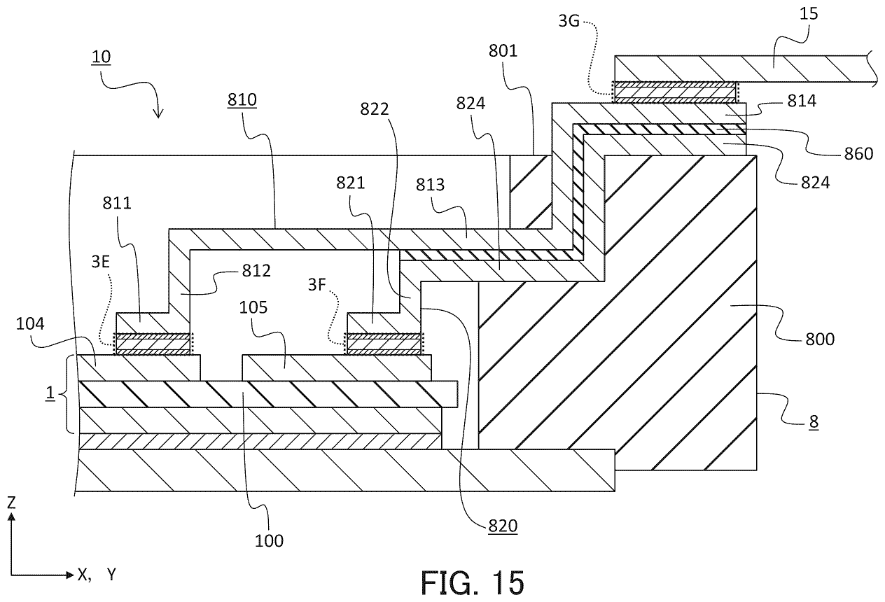

FIGS. 2A and 2B are diagrams illustrating a first manufacturing method of the joint structure according to the first embodiment. FIGS. 3A and 3B are diagrams illustrating how heat is transferred when the bonding material layer of the laminated bonding material is heated. The cross sections illustrated in FIGS. 2A and 2B correspond to the cross section in FIG. 1B. FIG. 3B may be a cross-sectional view illustrating a cross-sectional configuration along the alternate long and short dash line B-B′ in FIG. 3A, but hatching indicating a cross section is omitted. Here, the first manufacturing method of a joint structure in which the conductor pattern 110 and the lead terminal 2 of the wiring board 1 are bonded members is described, but the combination of bonded members is not limited to this. The combination of bonded members may be an electrode and a lead terminal on the top surface of a semiconductor element described below with reference to FIGS. 11 and 12 or may be an external terminal and a bus bar of a semiconductor device described below with reference to FIG. 15. In addition, in the first manufacturing method, a plurality of joint structures may be continuously manufactured.

The first manufacturing method of a joint structure includes an arrangement step and a bonding step. As illustrated in FIG. 2A, the arrangement step of the first manufacturing method may be a step of arranging a first bonding material sheet 311, the auxiliary conductor plate 300, a second bonding material sheet 321, and the bonded portion 200 of the lead terminal 2 on the conductor pattern 110 of the wiring board 1, in an overlapping manner. The first bonding material sheet 311 and the second bonding material sheet 321 correspond to the first bonding material layer 310 and the second bonding material layer 320 and may be sheets obtained by causing low melting point metal used as a bonding material such as tin or a tin alloy described above to be in a sheet shape (conductor foil). The first bonding material sheet 311, the auxiliary conductor plate 300, and the second bonding material sheet 321 may be separately laminated in this order and may be arranged in a laminate state in which the first bonding material sheet 311 and the second bonding material sheet 321 are pressed against the auxiliary conductor plate 300. The laminate obtained by pressing the first bonding material sheet 311 and the second bonding material sheet 321 against the auxiliary conductor plate 300 is an example of the laminated bonding material 3 obtained by laminating and integrating the first bonding material layer, the auxiliary conductor plate 300, and the second bonding material layer. In addition, a laminate obtained by pressuring one of the first bonding material sheet 311 and the second bonding material sheet 321 against the auxiliary conductor plate 300 and the other of the first bonding material sheet 311 and the second bonding material sheet 321 are laminated. The laminate of the first bonding material sheet 311, the auxiliary conductor plate 300, and the second bonding material sheet 321 may press (adhere) the top surface of the second bonding material sheet 321 before the arrangement step against the bottom surface of the bonded portion 200 of the lead terminal 2. Note that with respect to the conductor pattern 110, the back surface of the top surface facing the auxiliary conductor plate 300, that is, the back surface of the conductor pattern 110 may be in direct contact with the insulating layer (insulating substrate 100) and may be bonded to the insulating layer via the brazing material or the like.

As illustrated in FIG. 2B, in the bonding step performed after the arrangement step, the top surface of the bonded portion 200 is irradiated with laser 6 from the upper portion of the bonded portion 200 of the lead terminal 2 to heat and melt the second bonding material sheet 321 and the first bonding material sheet 311. In other words, the back surface of the surface facing the auxiliary conductor plate 300 in the lead terminal 2, that is, the top surface of the bonded portion 200 of the lead terminal 2 is irradiated with the laser 6. The irradiation condition of the laser 6 preferably satisfies the condition in which the second bonding material sheet 321 and the first bonding material sheet 311 are melted, and the lead terminal 2 and the conductor pattern 110 are bonded via the laminated bonding material 3, thereby performing heat conduction type welding. The heat conduction type welding is a welding mode in which only a bonding material such as low melting point metal is melted and bonded without melting a bonded member. A preferable example of the irradiation condition of the laser 6 is described below.

In the bonding step, the inside of an irradiation area 600 is irradiated with laser corresponding to the irradiation diameter of the laser 6 on the entire top surface of the bonded portion 200 of the lead terminal 2. The irradiation area 600 is not limited to a circular shape and may be an elliptical shape and the like. In the bonded portion 200 of the lead terminal 2 illustrated in FIG. 3A, each of the two irradiation areas 600 is irradiated with the laser 6 in a predetermined irradiation condition in which the heat conduction type welding is performed. When the bonded portion 200 of the lead terminal 2 is irradiated with the laser 6, the temperature of the inside of the irradiation area 600 in the bonded portion 200 rises, and as illustrated with the arrow in FIG. 3B, heat is conducted from the bonded portion 200 to the second bonding material sheet 321 of the laminated bonding material 3. A portion of the heat conducted to the second bonding material sheet 321 melts the second bonding material sheet 321, and the remaining heat is conducted to the auxiliary conductor plate 300. The heat conducted to the auxiliary conductor plate 300 is absorbed by the auxiliary conductor plate 300, is conducted to the first bonding material sheet 311 while being conducted to be diffused to the outside of the irradiation area 600 in the auxiliary conductor plate 300, and melts the first bonding material sheet 311. That is, the auxiliary conductor plate 300 that has a higher melting point than the bonding material sheet between the first bonding material sheet 311 and the second bonding material sheet 321 and good heat conductivity, so that it is possible to suppress direct conduction of the heat generated by the lead terminal 2 by the laser irradiation locally to the first bonding material sheet 311. In addition, the conduction of the heat in the auxiliary conductor plate 300 to be diffused to the outside of the irradiation area 600 can reduce a temperature difference between a portion to be the inside of the irradiation area 600 and a portion to be the outside of the irradiation area 600 in a plan view in the first bonding material sheet 311 and the second bonding material sheet 321. That is, in the first manufacturing method of a joint structure according to the present embodiment, local excessive temperature increases in the first bonding material sheet 311 and the second bonding material sheet 321 can be suppressed, the entire portion of the first bonding material sheet 311 and the second bonding material sheet 321 can be uniformly heated and melted.

When the lead terminal 2, the second bonding material sheet 321, and the auxiliary conductor plate 300 are heated, and the second bonding material sheet 321 is melted, the material of the external surface of the lead terminal 2 and the material of the second bonding material sheet 321 which are in contact with each other, and the material of the second bonding material sheet 321 and the material of the auxiliary conductor plate 300 which are in contact with each other form alloys thereof at the respective interface layers between the external surface of the lead terminal 2 and the second bonding material sheet 321 and between the second bonding material sheet 321 and the auxiliary conductor plate 300, thereby being solidified and firmly bonded. Similarly, when the auxiliary conductor plate 300, the first bonding material sheet 311, and the conductor pattern 110 are heated, and the first bonding material sheet 311 is melted, the material of the auxiliary conductor plates 300 and the material of the first bonding material sheet 311 which are in contact with each other, and the material of the first bonding material sheet 311 and the material of the external surface of the conductor pattern 110 which are in contact with each other form alloys thereof at the respective interface layers between the auxiliary conductor plates 300 and the first bonding material sheet 311 and between the first bonding material sheet 311 and the external surface of the conductor pattern 110, thereby being solidified and firmly bonded. Therefore, when the laminated bonding material 3 is uniformly heated, the alloy composition, grain size, and distribution also become uniform, and the bondability becomes good. In contrast, when the bonding material between the bonded members is unevenly heated, as in the case where the auxiliary conductor plate 300 is not present, a portion of the alloys formed with the material of the external surface of the bonded member and the material of the bonding material becomes coarse or fine, the distribution of each alloy also becomes uneven, and bondability (bonding strength) resultantly decreases. Therefore, in the first manufacturing method capable of uniformly heating and melting the first bonding material sheet 311 and the second bonding material sheet 321, uniform bondability (for example, the bonding strength and positional accuracy) can be realized compared with the manufacturing method of a joint structure in the related art by melting the bonding material that does not have the auxiliary conductor plate 300.

Furthermore, in the first manufacturing method described above, since the bonding material sheets 311 and 321 are uniformly heated, it is possible to suppress the generation of voids in the bonding material layers 310 and 320 while the bonding material sheets 311 and 321 are respectively melted and afterward solidified to become the bonding material layers 310 and 320, respectively (see FIG. 1B). As described above, each of the bonding material layers 310 and 320 includes an alloy layer of the material of the bonding material sheets 311 and 321 and the material of the external surface of the bonded member, the alloy layer which is formed at the bonding interface with the bonded member. Therefore, for example, a uniform alloy layer can be form formed over the entire surface between the first bonding material layer 310 and the conductor pattern 110 of the wiring board 1 (the bonding interface) thereby improving the bonding strength between the conductor pattern 110 and the first bonding material layer 310. Similarly, the bonding strength between the first bonding material layer 310 and the auxiliary conductor plate 300, the bonding strength between the auxiliary conductor plate 300 and the second bonding material layer 320, and the bonding strength between the second bonding material layer 320 and the bonded portion 200 of the lead terminal 2 are also improved. Therefore, the joint structure manufactured by the first manufacturing method described above can improve the bonding reliability between the conductor pattern 110 and the lead terminal 2 compared with a structure bonded by a bonding material without the auxiliary conductor plate 300.

In addition, in the first manufacturing method described above, the laser output required for melting the second bonding material sheet 321 and the first bonding material sheet 311 can be reduced, and thus, for example, deformation, damage, and the like of the bonded portion 200 due to the irradiation of the top surface of the bonded portion 200 of the lead terminal 2 with laser can be prevented. In addition, the second bonding material sheet 321 and the first bonding material sheet 311 can be uniformly melted with the relatively small laser output, and thus it is possible to suppress the excessive temperature increase of the conductor pattern 110 of the wiring board 1. As a result, when insulating substrate 100 is arranged under the conductor pattern 110 that is the bonded member as illustrated in FIG. 3A, the thermal damage of the insulating substrate 100 such as the decrease in adhesion between the conductor pattern 110 and the insulating substrate 100 due to the heat for melting the first bonding material sheet 311 can be prevented.

The bonding between the conductor pattern 110 and the lead terminal 2 using the laminated bonding material 3 according to the first embodiment is performed by irradiation with the laser 6 under the irradiation condition in which the second bonding material sheet 321 and the first bonding material sheet 311 are melted to perform the heat conduction type welding as described above. Note that the laminated bonding material 3 is used, due to the diffusion of the heat in the auxiliary conductor plate 300, the entire first bonding material sheet 311 including a portion to be the outside of the irradiation area 600 with the laser 6 can be uniformly heated and melted. In addition, at this time, conditions in which the bonding material is not ablated and scattered or depleted are preferable.

Note that the irradiation condition with the laser 6 may be a condition in which a melting phenomenon is not generated in a portion of the first bonding material sheet 311 (a portion outside the irradiation area 600) when the bonding material without the auxiliary conductor plate 300 is melted. Furthermore, the irradiation condition with the laser 6 may be a condition under which keyhole type welding is partially (locally) performed. Note that the keyhole type welding is a welding type in which the thermal energy density of the laser to be applied is high, and a recess is formed on the external surface of metal irradiated with laser surface by ablation or the like. A state in which the recess is deepened to form a cavity is referred to as a “keyhole”. However, when there is a keyhole, the bonding strength becomes uneven. Therefore, the irradiation condition with the laser 6 is preferably a condition under which a heat conduction welding type is performed throughout the entire joint structure.

Also, after the laser irradiation, an irradiation mark may be formed on the top surface of the bonded portion 200 of the lead terminal 2 which is the irradiation surface. The irradiation mark is discoloration of the external surface, shallow indentations having a depth of about several tens μm of 100 μm or less, melting marks, and the like, which are caused by laser irradiation in a shape substantially equal to the shape (irradiation surface shape) of the laser irradiation area and may be roughened as compared with a plane other than the irradiation place. The irradiation condition with the laser 6 which causes the average depth of the irradiation marks (recesses) to be larger than 100 μm may cause shape deformation near the irradiation place of the bonded member (lead terminal 2). For this reason, the recesses of the irradiation marks may partially include recesses having a depth of 100 μm or more in a mixed manner, but the average depth is preferably 100 μm or less and more preferably 50 μm or less. That is, the irradiation condition with the laser 6 is preferably a condition under which the average depth thereof is 100 μm or less (more preferably 50 μm or less) as described above, even if an irradiation mark (a recess or a melting mark) is generated on the irradiation surface.

In one example, the laser 6 used in the bonding step can be Nd:YAG laser having a wavelength of 1064 nm, which belongs to near infrared. When the Nd:YAG laser is used, the light absorption rate for copper (Cu) used for the conductor pattern 110, the lead terminal 2, and the auxiliary conductor plate 300 can be about 1.5% for the fundamental wave having a wavelength of 1064 nm and about 35.6% for the second harmonic having a wavelength of 532 nm. That is, in the case of using the Nd:YAG laser, when the lead terminal 2 is irradiated with the laser 6 whose wavelength is shortened by wavelength conversion (in other words, of the second harmonic), the light absorption rate at the lead terminal 2 is greatly improved (about 24 times). Therefore, when the conductor such as the lead terminal 2 to be bonded by the laminated bonding material 3 is copper or a conductor obtained by forming a coating film of nickel or the like on the copper surface, the bonding can be more efficiently performed than in the case of using green laser of the second harmonic (wavelength: 532 nm) as the Nd:YAG laser applied in the bonding step. Note that the laser 6 used in the bonding step is not limited to the Nd:YAG laser described above. The wavelength of the laser 6 used in the bonding step is preferably a wavelength having a high light absorption rate for the material of the bonded member such as the lead terminal 2 to be irradiated. In one example, the wavelength of the laser 6 is less than 1100 nm and is particularly preferably in the range of 500 nm to 550 nm. The laser 6 is not limited to the green laser described above and may be, for example, blue laser having a wavelength of 450 nm or the like or laser having another wavelength.

Also, the laser used in the bonding step may be pulse laser. In the heat conduction type welding using pulse laser, the maximum output energy of the laser is preferably within a range of 900 J/Pulse to 3000 J/Pulse and particularly preferably 1800 J/Pulse or more. Note that the pulse laser applied to the bonded member such as the lead terminal 2 is not limited to laser having a specific pulse width. In the heat conduction type welding using the pulse laser, as the pulse width is longer, the irradiation energy is temporally dispersed, the maximum attainment temperature in the irradiation area 600 in the base material decreases, and the light absorption rate increases. The pulse width may be, for example, 2.4 ms to 4.0 ms. Also, the laser irradiation diameter (diameter) can be 0.2 mm to 15 mm, and is selected in accordance with the bonding area, but is preferably 0.3 mm to 3 mm from the viewpoint of heat equalizing properties. Also, the laser irradiation diameter is preferably 1/10 to ½ of the length of the short side of the top surface of the bonded portion 200 from the viewpoint of heat equalizing properties. The laser 6 has a circular shape or an elliptical shape on the irradiation surface (that is, the irradiation surface has a circular shape or an elliptical shape), and the irradiation diameter is, for example, a diameter when the laser 6 to be applied to the top surface of the bonded portion 200 of the lead terminal 2, which is the irradiation surface, has a circular shape, or a length of the major axis when the laser 6 has an elliptical shape.

Note that, when the bonded member is bonded using the laminated bonding material 3 of the present embodiment, the irradiation condition of the laser 6 in the bonding step can be set based on, for example, the compositions and thicknesses of the bonded member (for example, the conductor pattern 110 and the lead terminal 2), the first bonding material sheet 311, the second bonding material sheet 321, and the auxiliary conductor plate 300, and the composition and thickness of the insulating member arranged below the bonded member. In addition, the temperature of the laminated bonding material 3 during laser irradiation is preferably T1m+5° C. to T1m+30° C. and more preferably T1m+10° C. to T1m+20° C., where T1m is the melting point of the second bonding material sheet 321 in the central portion of the irradiation area.

### EXAMPLES

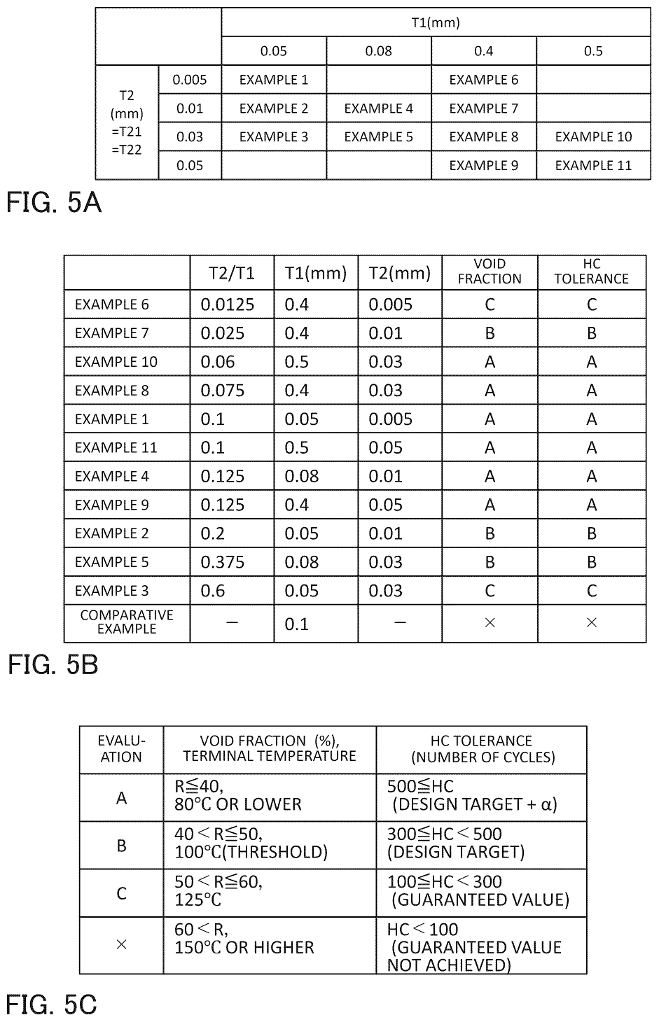

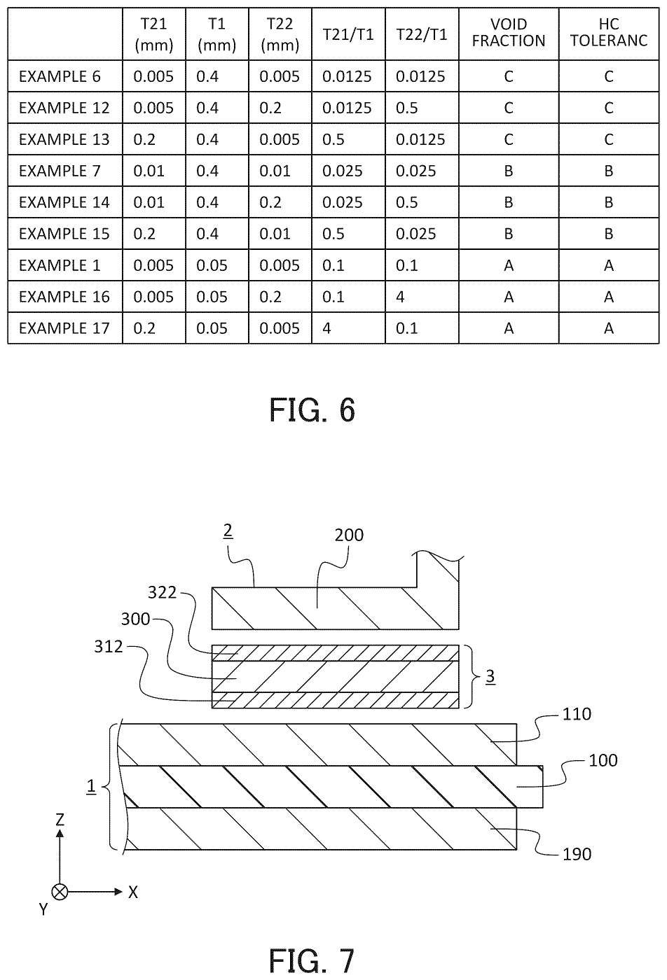

Hereinafter, the present invention is described in more detail with reference to examples of the present invention, but the present invention is not limited to the scope of the following examples. FIG. 4 is a diagram illustrating a thickness relationship of each layer of a laminated bonding material. In FIG. 4, only portions of the lead terminal 2 and the conductor pattern 110 of the wiring board 1, which are bonded members, to be bonded by the laminated bonding material 3 are illustrated. In the laminated bonding material 3 in the joint structure according to the first embodiment as illustrated in FIG. 4, it is preferable that a thickness T1 of the auxiliary conductor plate 300 is larger than a thickness T21 of the first bonding material layer 310 and a thickness T22 of the second bonding material layer 320. The thickness T1 of the auxiliary conductor plate 300 can be, for example, 0.05 mm≤T1≤0.5 mm. The thickness T21 of the first bonding material layer 310 and the thickness T22 of the second bonding material layer 320 may be 0.005 mm≤T21≤0.2 mm and 0.005 mm≤T22≤0.2 mm, respectively, and may be T21<T1 and T22<T1. A particularly preferable relationship among the relationships among the thicknesses T1, T21, and T22 of the layers satisfying such conditions is described with reference to FIGS. 5 and 6. FIGS. 5A to 5C are tables showing examples of preferable relationships between the thickness of the auxiliary conductor plate and the thickness of the bonding material layer. FIG. 6 is a table showing other examples of preferable relationships between the thickness of the auxiliary conductor plate and the thickness of the bonding material layer.

The table of FIG. 5A shows a combination of the thickness T1 of the auxiliary conductor plate 300 and a thickness T2 of the bonding material layer in each of Examples 1 to 11 of the present invention. In Examples 1 to 11, the thickness T21 of the first bonding material layer 310 and the thickness T22 of the second bonding material layer 320 are set to the same thickness (T21=T22=T2). The table of FIG. 5B shows the results obtained by examining the bonding reliability when the thickness of the lead terminal 2 irradiated with the laser 6 in the bonding step was set to 1.2 mm (see FIG. 4) for each of 11 combinations of Examples 1 to 11. Specifically, the bonding reliability between the bonded members that are bonded by each of the laminated bonding materials 3A to 3D in a semiconductor device 10 illustrated in FIGS. 11 and 12 and between other similar bonded members was examined. The bonded member was irradiated with the above-described green laser having a wavelength of 532 nm at 1800 J/Pulse with an irradiation diameter of 2 mm. In addition, in order to evaluate the presence of voids and unbonded portions between the bonded portion 200 of the lead terminal 2 and the conductor pattern 110, the electric resistance can be measured.

The table of FIG. 5B shows evaluation results of void fraction R (%) and heat cycle (HC) tolerance (number of cycles) defined from electric resistance as examples of values associated with bonding reliability. The void fraction R (%) is, for example, an electric resistance and a void occupancy in the bonding material layer derived by an ultrasonic flaw detection test and is a value indicating bonding reliability. Bondability in the joint structure including the lead terminal 2, the laminated bonding material 3, and the conductor pattern 110 and reliability as a semiconductor module were evaluated. The HC tolerance (cycle number) is the number of temperature cycles until the conductor pattern 110 and the lead terminal 2 are electrically insulated (open), when a temperature load is repeatedly applied, and is a value indicating the reliability of the semiconductor module. Specifically, the number of cycles in which the resistance increased by 20% from the predetermined resistance was defined as the HC tolerance. The temperature load was repeatedly applied with temperature changes in the order of 25° C., −40° C., 125° C., and 25° C. as one cycle. As a result, the results shown in the table of FIG. 5B were obtained at all the bonding places. Note that, in the table of FIG. 5B, in order to easily grasp the relationship between a ratio T2/T1 between the thickness T1 of the auxiliary conductor plate 300 and the thickness T2 of the bonding material layer and the bonding reliability, Examples 1 to 11 are arranged in ascending order of the ratio T2/T1. Also, the meanings of “A”, “B”, and “C” indicating the evaluation results of the void fraction R and the HC tolerance in the table of FIG. 5B are as shown in the table of FIG. 5C. Specifically, the evaluation “C” indicates that at least the required connection reliability is satisfied, and the evaluation “B” indicates that the connection reliability is in a preferable range higher than the evaluation “C”. In addition, the evaluation “A” indicates that the connection reliability is in a more preferable range which is higher than the preferable range of the evaluation “B”. The comparative example in the table of FIG. 5B may be a case where the conductor pattern 110 and the lead terminal 2 are bonded with a single bonding material (for example, a bonding material having the same composition as that of the first bonding material layer 310). The evaluation “x” of the void fraction R and HC tolerance in Comparative Example indicates that the required connection reliability is not satisfied.

From the table of FIG. 5B, it has been found that there is a reliable range of the ratio T2/T1 between the thickness T1 of the auxiliary conductor plate 300 and the thickness T2 of the bonding material layer. Specifically, when the thickness T21 of the first bonding material layer 310 and the thickness T22 of the second bonding material layer 320 are set to the same thickness T2, the void of the bonding portion can be reduced, the reliability can be improved by 60% or more, and the bonding reliability can be improved by setting within the range of 0.0125≤T2/T1≤0.6. When the ratio is within a range of 0.025≤T2/T1≤0.375, the bonding reliability is more enhanced, and when the ratio is within a range of 0.06≤T2/T1≤0.125, the bonding reliability is further enhanced. Moreover, the terminal temperature at the combination of the thicknesses T1 and T2 at which the void fraction R is evaluated as “B” is about 100° C., and the terminal temperature at the combination of the thicknesses T1 and T2 at which the void fraction R is evaluated as “A” is about 80° C. (see FIG. 5C). Therefore, by applying a combination of the thicknesses T1 and T2 in which the void fraction R is evaluated as “B” or “A”, it is possible to suppress an increase in the terminal temperature and to reduce the influence of the heat generated in the bonding step on the surrounding insulating member.

Note that, in the laminated bonding material 3 according to the first embodiment, the thickness T21 of the first bonding material layer 310 and the thickness T22 of the second bonding material layer 320 may be different. The table of FIG. 6 shows evaluation results of the void fraction R (%) and the HC tolerance (number of cycles) of Examples 12 to 17 in which the thickness T21 of the first bonding material layer 310 and the thickness T22 of the second bonding material layer 320 were set to different thicknesses. Examples 12 and 13 are examples which correspond to Example 6 in which the thickness T21 of the first bonding material layer 310 and the thickness T22 of the second bonding material layer 320 was set to the same thickness T2 (=0.005 mm), and in which one of the thickness T21 of the first bonding material layer 310 and the thickness T22 of the second bonding material layer 320 is made thicker than the thickness T2. That is, the ratio (T21/T1 of Example 12 and T22/T1 of Example 13) of the thickness of the thinner bonding material layer of the first bonding material layer 310 and the second bonding material layer 320 to the thickness T1 of the auxiliary conductor plate 300 in Examples 12 and 13 is the same value in T2/T1 of Example 6. The evaluation results of the void fractions R and the HC tolerances of Examples 12 and 13 were evaluated as “C”, which is the same as the evaluation result of Example 6. In addition, the evaluation results of Examples 14 and 15 in which any one of the thickness T21 of the first bonding material layer 310 and the thickness T22 of the second bonding material layer 320 was made thicker than the thickness T2 of Example 7, which corresponds to Example 7 in which the evaluation results of the void fraction R and the HC tolerance are represented by the evaluation “B”, were also evaluated as “B”. Further, the evaluation results of Examples 16 and 17 in which any one of the thickness T21 of the first bonding material layer 310 and the thickness T22 of the second bonding material layer 320 was made thicker than the thickness T2 of Example 1, which corresponds to Example 1 in which the evaluation results of the void fraction R and the HC tolerance are represented by the evaluation “A”, were also evaluated as “A”. That is, the evaluation results illustrated in the table of FIG. 6 suggest that, even when the thickness T21 of the first bonding material layer 310 is different from the thickness T22 of the second bonding material layer 320, as long as a ratio T2s/T1 of the thickness T2s of the thinner bonding material layer to the thickness T1 of the auxiliary conductor plate 300 is within the above-described range of T2/T1, the same connection reliability can be obtained regardless of the thickness of the thicker bonding material layer. However, when the thicker bonding material layer is too thick, it is difficult to uniformly melt the bonding material layer in the bonding step, and bonding reliability may be deteriorated. Therefore, the thickness of the thicker bonding material layer is preferably 0.2 mm or less.

### (Other Manufacturing Methods of Joint Structure According to First Embodiment)

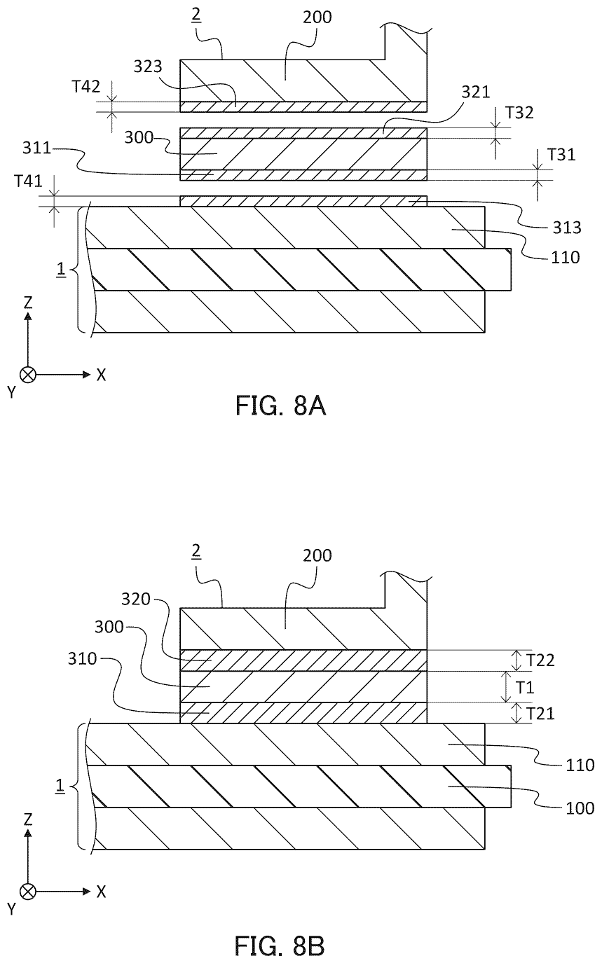

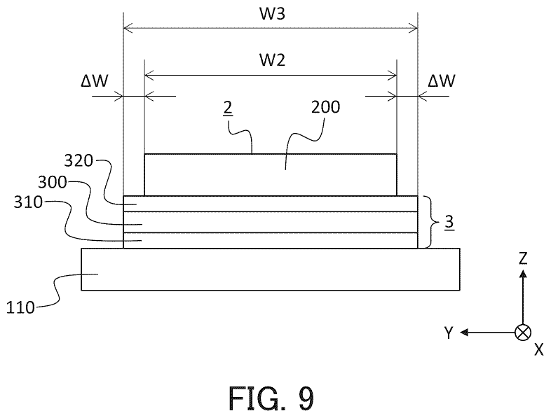

The manufacturing method of the joint structure according to the first embodiment is not limited to the above-described first manufacturing method. Other manufacturing methods of a joint structure according to the first embodiment are described with reference to FIGS. 7, 8A, and 8B. FIG. 7 is a cross-sectional view illustrating a second manufacturing method of a joint structure according to the first embodiment. FIGS. 8A and 8B are cross-sectional views illustrating a third manufacturing method of a joint structure according to the first embodiment. The cross sections illustrated in FIGS. 7, 8A, and 8B respectively correspond to the cross section of FIG. 2A (FIG. 1B). Here, the second and third manufacturing methods of a joint structure in which the conductor pattern 110 and the lead terminal 2 of the wiring board 1 are bonded members are described, but the combination of bonded members is not limited to this. The set of the bonded members may be an electrode and a lead terminal on the top surface of the semiconductor element described below with reference to FIGS. 9 and 10 or may be an external terminal and a bus bar of the semiconductor element. In addition, in the second and the third manufacturing methods, a plurality of joint structures may be continuously manufactured.

Similarly to the first manufacturing method, the second manufacturing method of a joint structure includes the arrangement step and the bonding step. In the arrangement step in the second manufacturing method, instead of laminating the first bonding material sheet 311, the auxiliary conductor plate 300, and the second bonding material sheet 321 described above, the auxiliary conductor plate 300 on which a bonding material layer of low melting point metal is formed (deposited) by plating or the like is arranged. That is, as illustrated in FIG. 7, in the arrangement step in the second manufacturing method, a first bonding material layer 312 and a second bonding material layer 322 are formed (deposited) on the bottom surface and the top surface of the auxiliary conductor plate 300 to arrange the laminate (laminated bonding material 3) obtained by integrating the layers between the conductor pattern 110 of the wiring board 1 and the lead terminal 2. After the auxiliary conductor plate 300 on which the first bonding material layer 312 and the second bonding material layer 322 are formed and the lead terminal 2 are arranged in the arrangement step, the bonding step is performed. In the bonding step, as described above, the second bonding material layer 322 and the first bonding material layer 312 are uniformly heated and melted by applying the laser 6 from the top surface of the bonded portion 200 of the lead terminal 2 under the irradiation condition under which the heat conduction welding type is performed, to bond the conductor pattern 110 and the lead terminal 2.

The first bonding material layer 312 and the second bonding material layer 322 can be formed (deposited) not only by a well-known plating method but also by ion plating, sputtering, or another method of growing a film of low melting point metal (for example, tin or a tin alloy) used as a bonding material on each of the bottom surface and the top surface of the auxiliary conductor plate 300. By using a structure obtained by depositing and integrating the bonding material layer on the auxiliary conductor plate 300 in this manner, it is possible to prevent bonding failure in the subsequent bonding step due to positional deviation between the bonding material and the auxiliary conductor plate 300 in the arrangement step. Each of the bonding material layers 312 and 322 can be, for example, tin plating (plating in which tin is 99 wt % or more) or tin-copper-based plating. In the case of tin-copper-based plating, the amount of copper is preferably 1 wt % to 12 wt % and more preferably 2 wt % to 10 wt %. The thickness of each of the bonding material layers 312 and 322 is not limited to a specific thickness, but the ratio T2s/T1 of the thickness T2s of the thinner bonding material layer in the bonding material layers 310 and 320 after the bonding step to the thickness T1 of the auxiliary conductor plate 300 is set within the range of T2/T1 described above. Also, the second manufacturing method may be combined with the first manufacturing method. In other words, the first bonding material layer 312 may include a bonding material film deposited on the bottom surface of the auxiliary conductor plate 300 and a bonding material sheet arranged on the bottom surface of the bonding material film. Similarly, the second bonding material layer 322 may include a bonding material film deposited on the top surface of the auxiliary conductor plate 300 and a bonding material sheet arranged on the top surface of the bonding material film.

Similarly to the first and second manufacturing methods, the third manufacturing method of the joint structure according to the first embodiment also includes the arrangement step and the bonding step. In the arrangement step in the third manufacturing method, a layer (bonding material layer) of low melting point metal used as a bonding material is arranged on a surface of the bonded member which faces the auxiliary conductor plate 300. That is, the arrangement step in the third manufacturing method includes a step of arranging a bonding material layer 313 on the top surface of the conductor pattern 110 of the wiring board 1 and a step of arranging a bonding material layer 323 on the bottom surface of the bonded portion 200 of the lead terminal 2 as illustrated in FIG. 8A. A bonding material layer 313 of the top surface of the conductor pattern 110 may be low melting point metal of the same composition as the first bonding material sheet 311 that is arranged on the bottom surface of the auxiliary conductor plate 300. A bonding material layer 323 of the bottom surface of the lead terminal 2 may be low melting point metal of the same composition as the second bonding material sheet 321 that is arranged on the top surface of the auxiliary conductor plate 300. The bonding material layer 313 of the top surface of the conductor pattern 110 and the bonding material layer 323 of the bottom surface of the bonded portion 200 of the lead terminal 2 may be arranged by pressing a sheet-shaped bonding material and may be arranged by forming (depositing) the first bonding material layer 312 and the second bonding material layer 322 using the second manufacturing method. Further, the first bonding material sheet 311 and the second bonding material sheet 321 may be laminated on the bottom surface and the top surface of the auxiliary conductor plate 300, or the first bonding material layer 312 and the second bonding material layer 322 used in the second manufacturing method may be formed (deposited). The auxiliary conductor plate 300 may have a configuration in which a bonding material layer is formed on one of the bottom surface and the top surface, and a bonding material sheet is arranged on the other of the bottom surface and the top surface. After the arrangement step, a bonding step is performed. In the bonding step, as described above, the bonding material layer 323, the second bonding material sheet 321, the first bonding material sheet 311, and the bonding material layer 313 are uniformly heated and melted by applying the laser 6 from the top surface of the bonded portion 200 of the lead terminal 2 under the irradiation condition under which the heat conduction welding type is performed, to bond the conductor pattern 110 and the lead terminal 2.

The bonding material layer 313 on the top surface of the conductor pattern 110 and the bonding material layer 323 of the bottom surface of the lead terminal 2 are each formed by depositing a film by plating, sputtering, or the like or by pressing a sheet material. A thickness T41 of the bonding material layer 313 of the top surface of the conductor pattern 110 and a thickness T31 of the first bonding material sheet 311 (or the first bonding material layer 312) of the bottom surface of the auxiliary conductor plate 300 are set so that the thickness T21 of the first bonding material layer 310 after the bonding step illustrated in FIG. 8B satisfies the condition described above. A thickness T42 of the bonding material layer 323 of the bottom surface of the lead terminal 2 and a thickness T32 of the second bonding material sheet 321 (or the second bonding material layer 322) of the top surface of the auxiliary conductor plate 300 are set so that the thickness T22 of the second bonding material layer 320 after the bonding step illustrated in FIG. 8B satisfies the condition described above.

In the third manufacturing method described above with reference to FIGS. 8A and 8B, the first bonding material sheet 311 (or the first bonding material layer 312) and the bonding material layer 313 of the top surface of the conductor pattern 110 are preferably materials of low melting point metal with the same composition from the viewpoint of uniformly heating and melting the both, but the compositions may be different. Similarly, the second bonding material sheet 321 (or the second bonding material layer 322) and the bonding material layer 323 of the bottom surface of the lead terminal 2 are preferably materials of low melting point metal with the same composition, but the compositions may be different. Also, when the bonding material layer 313 of the top surface of the conductor pattern 110 is formed (deposited) by plating or the like, for example, the bonding material layer 313 may be formed on the top surface of the conductor pattern 110 in the manufacturing step of the wiring board 1 or the like. The material of the external surface the conductor pattern 110 on which the bonding material layer 313 is formed may be, for example, copper or a copper alloy or may be nickel or the like coating the external surface of copper. Similarly, when the bonding material layer 323 of the bottom surface of the lead terminal 2 is formed (deposited) by plating or the like, for example, the bonding material layer 323 may be formed on the bottom surface of the lead terminal 2 in the manufacturing step of the lead terminal 2 or the like. The material of the external surface the lead terminal 2 on which the bonding material layer 323 is formed may be, for example, copper or a copper alloy or may be nickel or the like coating the external surface of copper. Note that, in the third manufacturing method, only one of the bonding material layer 313 of the conductor pattern 110 of the wiring board 1 and the bonding material layer 323 of the lead terminal 2 may be formed (deposited). When the bonding material layer 313 is formed on the conductor pattern 110, the first bonding material sheet 311 and the like on the bottom surface of the auxiliary conductor plate 300 may be omitted, and when the bonding material layer 323 is formed on the lead terminal 2, the second bonding material sheet 321 and the like on the top surface of the auxiliary conductor plate 300 may be omitted.

Note that the manufacturing method of the joint structure according to the first embodiment is not limited to the above-described first to third manufacturing methods. The joint structure may be manufactured by arranging the bonding material layer and the auxiliary conductor plate 300 on one of the bonded members in advance, and then bonding the auxiliary conductor plate to the other of the bonded members on which the bonding material layer is formed. For example, first, the bonding material layer 323 and the auxiliary conductor plate 300 are arranged (temporarily bonded) on the bottom surface of the bonded portion 200 of the lead terminal 2 by pressing or heating, and the auxiliary conductor plate 300 is bonded to the lead terminal 2 via the bonding material layer 323. Meanwhile, the bonding material layer 313 is also arranged on the top surface of the conductor pattern 110 of the wiring board 1 by pressure pressing or deposition. Then, the bottom surface side of the lead terminal 2 on which the bonding material layer 323 and the auxiliary conductor plate 300 are laminated and the conductor pattern 110 of the wiring board 1 on which the bonding material layer 313 is formed are arranged and bonded. In this example, the bonding material layer 313 and the auxiliary conductor plate 300 may be laminated in advance on the top surface of the conductor pattern 110 of the wiring board 1.

(Supplement with Respect to Dimension in Joint Structure of First Embodiment)

FIG. 9 is a diagram supplementing a dimensional relationship between a bonded member and a laminated bonding material in the joint structure of the first embodiment.

The laminated bonding material 3 according to the first embodiment preferably has a dimension so that the entire bonded surface of the bonded member having a smaller area of the bonded surface among the two bonded members to be bonded is bonded to the bonding material layer of the laminated bonding material 3. The “bonded surface” in the present specification intends the entire one surface including a bonding area with the bonding material layer of the laminated bonding material 3 in the bonded member, and thus both a case where the entire bonded surface is the bonding area and a case where the bonded surface includes the bonding area and the non-bonding area around the bonding area may be possible. The bonded surface of the lead terminal 2 illustrated in FIG. 1B and the like is a bottom surface of the bonded portion 200 and is a bonding area where the entire bonded surface is bonded to the second bonding material layer 320. In addition, the bonded surface of the conductor pattern 110 illustrated in FIG. 1B and the like is a top surface and includes a bonding area bonded to the first bonding material layer 310 and a non-bonding area around the bonding area. In the conductor pattern 110 of the wiring board 1 and the bonded portion 200 of the lead terminal 2 illustrated in FIG. 1B and the like, the bonded portion 200 of the lead terminal 2 has a smaller area of the bonded surface. Therefore, the laminated bonding material 3 preferably has a dimension so that the entire bottom surface of the bonded portion 200 of the lead terminal 2 is a bonding area to the second bonding material layer 320. However, the dimension of the laminated bonding material 3 is not limited to the dimension in which the top surface of the second bonding material layer 320 and the bottom surface of the bonded portion 200 of the lead terminal 2 illustrated in FIG. 1B and the like have substantially the same area.

With respect to the dimension of the laminated bonding material 3, for example, as illustrated in FIG. 9, a dimension W3 of the auxiliary conductor plate 300 may be larger than a dimension W2 of the bonded portion 200 of the lead terminal 2. In the laminated bonding material 3, the dimensions of the first bonding material sheet 311 or the first bonding material layer 312, and the second bonding material sheet 321 or the second bonding material layer 322 before being melted by laser are also substantially the same dimension W3 as the auxiliary conductor plate 300 and are larger than the dimension W2 of the bonded portion 200 of the lead terminal 2. Therefore, for example, when the laminated bonding material 3 and the lead terminal 2 are arranged on the conductor pattern 110 of the wiring board 1, even in a case where the positions of the laminated bonding material 3 and the bonded portion 200 of the lead terminal 2 are deviated in the plan view of the top surface of the conductor pattern 110, the entire bonded surface (bottom surface) of the bonded portion 200 of the lead terminal 2 can be bonded to the second bonding material layer 320. Therefore, it is possible to suppress variations in electrical characteristics, bonding strength, and the like caused by variations in the bonding area for each product (for example, for each semiconductor device 10 described below). When the dimension W3 of the laminated bonding material 3 (auxiliary conductor plate 300) is increased, the material cost may be increased, and the miniaturization may be hindered. Therefore, the difference (2×ΔW=W3−W2) between the dimension W3 of the laminated bonding material 3 (auxiliary conductor plate 300) and the dimension W2 of the bonded portion 200 of the lead terminal 2 is preferably, for example, in the range of 0 mm to 10 mm. Note that, although FIG. 9 illustrates only the dimensional difference in the Y-direction, there may be a similar dimensional difference in the X-direction.

### (Modification of Laminated Bonding Material of First Embodiment)

FIG. 10A is a plan view illustrating a modification of the laminated bonding material according to the first embodiment, and FIG. 10B is a cross-sectional view illustrating a cross-sectional configuration taken along an alternate long and short dash line C-C′ in FIG. 10A. Note that, in FIG. 10B, hatching indicating that each component is a cross section is omitted.

The laminated bonding material 3 according to the first embodiment diffuses heat conducted from the lead terminal 2 to the auxiliary conductor plate 300 via the second bonding material sheet 321 or the like in the auxiliary conductor plate 300 and suppresses direct and local heat conduction to the first bonding material sheet 311 or the like. That is, the auxiliary conductor plate 300 of the laminated bonding material 3 may have a shape capable of suppressing direct and local heat conduction to the first bonding material sheet 311 and the like and is not limited to the shape in which the top surface and the bottom surface are flat as illustrated in FIG. 1B and the like. For example, as illustrated in FIGS. 10A and 10B, a through hole 301 penetrating from the top surface to the bottom surface may be formed in the auxiliary conductor plate 300. In addition, it is preferable to cause a hole diameter R2 of the through hole 301 to be smaller than the dimension (irradiation diameter R1) of the irradiation area 600 with laser, because a portion of the heat in the irradiation area 600 is conducted to the auxiliary conductor plate 300 and diffused in the auxiliary conductor plate 300. The hole diameter R2 of the through hole 301 is preferably in the range of R1/10 to R1/2, and if the hole diameter is in this range, direct and local heat conduction to the first bonding material sheet 311 or the first bonding material layer 312 can be suppressed. Therefore, as compared with the case where the auxiliary conductor plate 300 is not arranged, direct and local heat conduction to a portion of the bonding material close to the bonding interface with the conductor pattern 110 of the wiring board 1 is suppressed. In addition, the bonding material arranged above the auxiliary conductor plate 300 and the bonding material arranged under the auxiliary conductor plate are melted to enter the through hole 301, the first bonding material layer 310 and the second bonding material layer 320 are in a state of being integrated by a bonding material 330 in the through hole 301 of the auxiliary conductor plate 300 after the bonding step. Therefore, although the heat equalizing properties are inferior to that of the auxiliary conductive plate without a plate-shaped through hole, for example, delamination at the interface between the first bonding material layer 310 and the auxiliary conductor plate 300, delamination at the interface between the second bonding material layer 320 and the auxiliary conductor plate 300, and the like hardly occur.

Note that the position of the through hole 301 is not limited to the position within the irradiation area 600 with laser illustrated in FIGS. 10A and 10B. When the auxiliary conductor plate 300 in which the through hole 301 is formed is used, for example, the through hole 301 is preferably formed at a position deviated from the central portion of the irradiation area 600 with laser so as not to partially or entirely overlap the irradiation area 600 in plan view, because direct and local heat conduction to the first bonding material sheet 311 and the like can be suppressed. Instead of the through hole 301, a notch may be provided at a position that becomes an end portion (for example, a corner portion) of the auxiliary conductor plate 300 in plan view, and the first bonding material layer 310 in the lower portion of the auxiliary conductor plate 300 and the second bonding material layer 320 in the upper portion may be integrated by the bonding material 330 along the notch. Note that the main purposes of the auxiliary conductor plate 300 are to suppress direct and local heat conduction from one bonded member (lead terminal 2) to the other bonded member (conductor pattern 110) and to uniformly heat a bonding material (low melting point metal) by heat diffusion in the auxiliary conductor plate 300. Therefore, the laminated bonding material 3 using a cloth-shaped member or a net-shaped member containing metal fibers as the auxiliary conductor plate 300 is a form in which the effect of suppressing direct and local heat conduction to the first bonding material sheet 311 or the first bonding material layer 312 is not large as compared with a form using the auxiliary conductor plate 300 provided with a flat plate shape or a small through hole or notch in a portion of a flat plate.

The laminated bonding material 3 in the joint structure according to the first embodiment is not limited to the three-layer structure described above. The laminated bonding material 3 may have a configuration in which the plurality of auxiliary conductor plates 300 are alternately laminated with the bonding material layers between the first bonding material layer 310 and the second bonding material layer 320. In this example, the plurality of auxiliary conductor plates 300 may have the same material and shape (thickness), or two or more types of auxiliary conductor plates having different materials or shapes may be combined. In addition, the first bonding material layer 310 and the second bonding material layer 320 in the laminated bonding material 3 are not limited to the same material, and for example, materials having different materials may be selected according to the material of the external surface of the bonded member that is bonded to the first bonding material layer 310 and the material of the external surface of the bonded member that is bonded to the second bonding material layer 320.

The joint structure and the manufacturing method of the joint structure described in the first embodiment can be applied to, for example, a semiconductor device used for a power converter such as a vehicular or other industrial inverter device, and a manufacturing method of the semiconductor device. Examples of the semiconductor device to which the joint structure according to the first embodiment can be applied are described below as second to fourth embodiments. The “semiconductor device” in the present specification is obtained by sealing a semiconductor element that may be referred to as a semiconductor chip, a die, or the like with an insulating material, and may be referred to as a “semiconductor module” or the like. In addition, the following second to fourth embodiments are merely examples of a semiconductor device to which the joint structure according to the first embodiment can be applied. The joint structure and the manufacturing method of the joint structure described in the first embodiment can be applied to various semiconductor devices or other devices or structures which have a joint structure in which bonded members are bonded to each other by heat conduction type welding using a bonding material and which are not described in detail in the present specification.

### Second Embodiment: Semiconductor Device

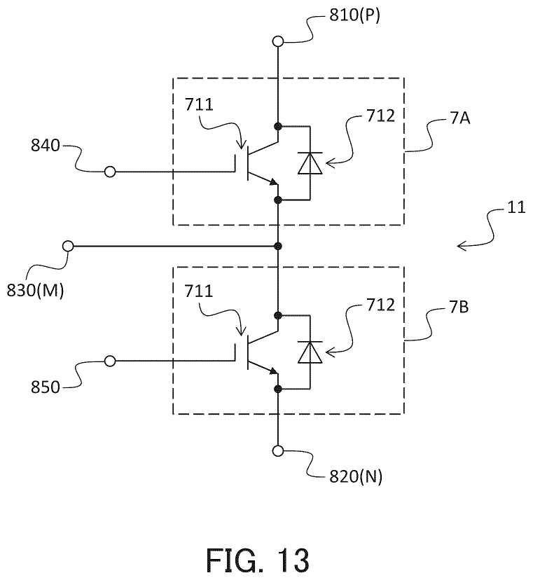

FIG. 11 is a diagram illustrating a configuration example of a semiconductor device according to a second embodiment. FIG. 12 is a cross-sectional view illustrating a cross-sectional configuration taken along an alternate long and short dash line D-D′ in FIG. 11. FIG. 13 is a circuit diagram illustrating an inverter circuit formed in the semiconductor device. In the following description of the second embodiment, detailed description of the components described in the first embodiment is omitted.

As illustrated in FIGS. 11 and 12, the semiconductor device 10 according to the second embodiment includes the wiring board 1, lead terminals 2A and 2B, the laminated bonding materials 3A to 3D, the heat dissipation plate 4, semiconductor elements 7A and 7B, and a case 8. In the semiconductor device 10 of FIGS. 11 and 12, a half-bridge inverter circuit 11 illustrated in FIG. 13 is formed.

In the wiring board 1, the first conductor pattern 110, a second conductor pattern 120, and a third conductor pattern 130 are arranged on the top surface of the insulating substrate 100 that is the insulating layer, and the heat dissipation layer 190 is arranged on the bottom surface of the insulating substrate 100. The insulating substrate 100 may be a ceramic substrate but may be a resin insulating substrate. The wiring board 1 is arranged on the top surface of the heat dissipation plate 4, and the heat dissipation layer 190 of the wiring board 1 and the heat dissipation plate 4 are bonded by a bonding material 5A. Also, the first semiconductor element 7A is arranged on the top surface of the first conductor pattern 110, and the second semiconductor element 7B is arranged on the top surface of the second conductor pattern 120. The first semiconductor element 7A and the second semiconductor element 7B can be, for example, a reverse conducting (RC)-IGBT element in which an insulated gate bipolar transistor (IGBT) element 711 and a diode element 712 connected in antiparallel to the IGBT element 711 are integrated as illustrated in FIG. 13. The diode element 712 may be, for example, a free wheeling diode (FWD) element. However, the present invention is not limited thereto.

A collector electrode 701 functioning as a collector of the IGBT element 711 and a cathode of the diode element 712 is arranged on the bottom surfaces of the first semiconductor element 7A and the second semiconductor element 7B. The collector electrode 701 of the first semiconductor element 7A is bonded to the first conductor pattern 110 of the wiring board 1 by a bonding material (not illustrated). The collector electrode 701 of the second semiconductor element 7B is bonded to the second conductor pattern 120 of the wiring board 1 by a bonding material 5B. The collector electrode 701 may be referred to as a back electrode. In addition, the collector electrode 701 may also be referred to as a lower electrode or a bottom surface electrode when facing the conductor pattern of the wiring board 1 as illustrated in the drawing.

An emitter electrode 702 functioning as an emitter of the IGBT element 711 and an anode of the diode element 712 and a gate electrode 703 functioning as a gate of the IGBT element 711 are arranged on the top surface of the first semiconductor element 7A and the second semiconductor element 7B. The emitter electrode 702 of the first semiconductor element 7A is electrically connected to the second conductor pattern 120 of the wiring board 1 via the lead terminal 2A. The lead terminal 2A has two bonded portions, one bonded portion is bonded to the emitter electrode 702 of the first semiconductor element 7A by a laminated bonding material (not illustrated), and the other bonded portion is bonded to the second conductor pattern 120 of the wiring board 1 by another laminated bonding material (not illustrated). The emitter electrode 702 of the second semiconductor element 7B is electrically connected to the third conductor pattern 130 of the wiring board 1 via the lead terminal 2B. The lead terminal 2B has two bonded portions, one bonded portion is bonded to the third conductor pattern 130 by the laminated bonding material 3A, and the other bonded portion is bonded to the emitter electrode 702 of the second semiconductor element 7B by another laminated bonding material 3B. When the emitter electrode 702 is in a state of being arranged on the surface (that is, the top surface) opposite to the surface facing the conductor pattern of the wiring board 1 in the semiconductor elements 7A and 7B as illustrated, the emitter electrode may be referred to as an upper electrode or a top surface electrode.

In the semiconductor device 10 illustrated in FIGS. 11 and 12, the annular case 8 of which an upper end and a lower end are opened and which surrounds the wiring board 1 in a plan view of the top surface of the heat dissipation plate 4 is arranged on the top surface of the heat dissipation plate 4. The case 8 includes an annular case body portion 800 made of an insulating material such as an epoxy resin or a polyphenylene sulfide (PPS) resin, and lead terminals 810, 820, 830, 840, and 850 integrated with the case body portion 800. Each of the lead terminals 810, 820, 830, 840, and 850 includes an inner terminal portion that is electrically connected to a conductor in a space surrounded by the case body portion 800 and an outer terminal portion that extends upward from the top surface of the case body portion 800 and functions as an external terminal of the semiconductor device 10. The first lead terminal 810, the second lead terminal 820, and the third lead terminal 830 are main terminals through which a current converted from DC to AC by the inverter circuit flows. The first lead terminal 810 and the second lead terminal 820 are, for example, input terminals in an inverter circuit which are connected to a positive electrode and a negative electrode of an external DC power supply, respectively. An inner terminal portion of the first lead terminal 810 is bonded to the first conductor pattern 110 of the wiring board 1 by a laminated bonding material (not illustrated). An inner terminal portion of the second lead terminal 820 is bonded to the third conductor pattern 130 of the wiring board 1 by the laminated bonding material 3C. The third lead terminal 830 is, for example, an output terminal in an inverter circuit connected to a load. An inner terminal portion of the third lead terminal 830 is bonded to the second conductor pattern 120 of the wiring board 1 by the laminated bonding material 3D. The fourth lead terminal 840 and the fifth lead terminal 850 are a control terminal that applies a control signal to the gate electrode 703 of the first semiconductor element 7A and a control terminal that applies a control signal to the gate electrode 703 of the second semiconductor element 7B, respectively. The inner terminal portion of the fourth lead terminal 840 is electrically connected to the gate electrode 703 of the first semiconductor element 7A by a wire 9A, and the inner terminal portion of the fifth lead terminal 850 is electrically connected to the gate electrode 703 of the second semiconductor element 7B by a wire 9B. The semiconductor device 10 may include an auxiliary control terminal and the like not illustrated in FIGS. 11 and 12.

In the semiconductor device 10 illustrated in FIGS. 11 and 12, the top surfaces of the bonded portions of the lead terminals 2A and 2B and the inner terminal portions (bonded portions) of the first lead terminal 810, the second lead terminal 820, and the third lead terminal 830 of the case 8 are exposed before the sealing resin is filled in the space surrounded by the case body portion 800, and can be irradiated with a laser beam. Therefore, each of the bonded portions of the lead terminals 2A, 2B, 810, 820, and 830 described above can be bonded to a bonding partner (bonded member) using the laminated bonding material 3 described in the first embodiment.

The conductor pattern 110 of the wiring board 1 and the first lead terminal 810 of the case 8 are bonded by a laminated bonding material (not illustrated), and a joint structure similar to the joint structure in which the conductor pattern 110 of the wiring board 1 and the bonded portion 200 of the lead terminal 2 described in the first embodiment are bonded by the laminated bonding material 3 is formed. A joint structure obtained by bonding the third conductor pattern 130 of the wiring board 1 and the lead terminal 2B by the laminated bonding material 3A and a joint structure obtained by bonding the third conductor pattern 130 and the second lead terminal 820 by the laminated bonding material 3C each are the same structure as the joint structure described in the first embodiment. A joint structure obtained by bonding the second conductor pattern 120 and the third lead terminal 830 of the wiring board 1 by the laminated bonding material 3D is also the same structure as the joint structure described in the first embodiment. The emitter electrode 702 of the semiconductor element 7A and the lead terminal 2A are bonded by a laminated bonding material (not illustrated), and a joint structure in which the conductor pattern 110 in the joint structure described in the first embodiment is replaced with an upper electrode (emitter electrode 702) of the semiconductor element 7A is formed. The joint structure in which the emitter electrode 702 of the semiconductor element 7B and the lead terminal 2B are bonded by the laminated bonding material 3B is a structure in which the conductor pattern 110 in the joint structure described in the first embodiment is replaced with the upper electrode (emitter electrode 702) of the semiconductor element 7B. A plurality of laminated bonding materials in one semiconductor device 10 including the illustrated laminated bonding materials 3A to 3D may or may not have the same laminated configuration in which all of the laminated bonding materials are combined with the same material. For example, the laminated bonding material 3A that bonds the lead terminal 2B and the conductor pattern 130 illustrated in FIG. 12 and the laminated bonding material 3B that bonds the lead terminal 2B and the emitter electrode 702 of the semiconductor element 7B be a combination of the same materials, and the combinations of the thicknesses of the layers may be different.

Note that, in the semiconductor device 10 of the second embodiment, for example, some of the four laminated bonding materials 3A to 3D illustrated in FIG. 12 may be electrically connected in another form not using the laminated bonding material 3. For example, in the semiconductor device 10, the upper electrode (emitter electrode 702) of the semiconductor element and the conductor pattern of the wiring board 1 may be electrically connected by a wire instead of the lead terminal 2. In the semiconductor device 10, for example, a plurality of semiconductor elements may be arranged on the first conductor pattern 110 and the second conductor pattern 120 of the wiring board 1, respectively. The plurality of semiconductor elements arranged on one conductor pattern may include, for example, a semiconductor element functioning as a switching element such as an IGBT element and a semiconductor element functioning as a diode element such as an FWD element.

The outer terminal portions of the first lead terminal 810, the second lead terminal 820, and the third lead terminal 830 of the case 8 may be bent in a direction along the top surface of the case body portion 800. The case 8 may be provided with an additional lead terminal different from the lead terminals 810, 820, 830, 840, and 850 illustrated in FIG. 11. The additional lead terminal may include, for example, a lead terminal that is electrically connected to the emitter electrode 702 of the semiconductor element 7A and functions as a first auxiliary control terminal, and a lead terminal that is electrically connected to the emitter electrode 702 of the semiconductor element 7B and functions as a second auxiliary control terminal. The first auxiliary control terminal may be connected to a gate drive circuit that generates a control signal to be applied to the gate of the IGBT element 711 via the fourth lead terminal 840, and the second auxiliary control terminal may be connected to a gate drive circuit that generates a control signal to be applied to the gate of the IGBT element 711 via the fifth lead terminal 850.

The heat dissipation plate 4 may be a plate-shaped metal plate, may be a plate in which fins extending downward from the bottom surface are formed, or may have a cooler having a water jacket or the like having fins. That is, the heat dissipation plate 4 may be one of components that configure a cooler 12 arranged below (indicated by an alternate long and two short dashes line in FIG. 12) or may be a component different from cooler 12 attached to the cooler 12. The cooler 12 radiates heat conducted from the semiconductor elements 7A and 7B via the wiring board 1 and the heat dissipation plate 4 to cool the semiconductor elements 7A and 7B. For example, the heat dissipation plate 4 or the cooler 12 may be units so that the plurality of semiconductor devices 10 having the planar configuration illustrated in FIG. 12 can be arranged in parallel (for example, in the Y-direction). The cooler 12 is not limited to a unit having a particular cooling scheme and structure. In addition, the heat dissipation plate 4 itself may function as a cooler, and the cooler 12 may be omitted.

### (Manufacturing Method of Semiconductor Device)

The manufacturing step of the semiconductor device 10 according to the second embodiment includes, for example, a first arrangement step, a first bonding step, a second arrangement step, and a second bonding step. The first arrangement step may be a step of arranging the bonding material 5A, the wiring board 1, the bonding material 5B, and the semiconductor elements 7A and 7B on the top surface of the heat dissipation plate 4. The bonding material 5A and the bonding material 5B may be, for example, plate solder. The first bonding step may be a step of heating and melting the bonding material 5A and the bonding material 5B, bonding the heat dissipation plate 4 and the heat dissipation layer 190 of the wiring board 1, and bonding the conductor pattern of the wiring board 1 and the collector electrodes 701 of the semiconductor elements 7A and 7B. The first bonding step may be the same as a known reflow step. Further, the bonding material 5A and the bonding material 5B may be bonding materials having a silver sintered material.

The second arrangement step includes, for example, a step of arranging the laminated bonding material 3 on the conductor pattern of the wiring board 1 and on the emitter electrode 702 of the semiconductor elements 7A and 7B, a step of arranging the lead terminals 2A and 2B, and a step of arranging the case 8. The step of arranging the case 8 may include, for example, a step of adhering the case body portion 800 of the case 8 to the top surface of the heat dissipation plate 4 with an adhesive. In the second arrangement step, the auxiliary conductor plate 300 that configures the laminated bonding material 3 and the bonding material layers above and below the auxiliary conductor plate are arranged by, for example, any one of the three methods described in the first embodiment and other possible methods. In the second bonding step, laser is applied in the manner described in the first embodiment for each bonded portion of the bonded member that is bonded by the laminated bonding material 3 to form the joint structure bonded by heat conduction type welding. Note that the manufacturing method of the semiconductor device 10 according to the second embodiment may include, after the second bonding step, a step of filling a sealing resin in a recess surrounded by the case body portion 800 of the case 8, a step of closing an opening at an upper end of the case body portion 800 with a lid member, and the like.

As described above, the laminated bonding material 3 having the auxiliary conductor plate 300 is used, and the bonded portion or the like of the lead terminal 2A is irradiated with laser from above under the irradiation condition of being bonded by heat conduction type welding, whereby the insulating substrate 100 positioned below the irradiation area with laser can be prevented from being directly and locally heated to a high temperature. Therefore, the insulating substrate 100 can be prevented from being thermally damaged, and for example, the reliability of the semiconductor device 10 can be prevented from being lowered due to a decrease in adhesion between the conductor patterns 120 and 130 and the like and the insulating substrate 100, and heat conduction to the heat dissipation plate 4 via the wiring board 1 can be prevented from being hindered. In addition, as described in the first embodiment, since the bonded members can be uniformly bonded by using the laminated bonding material 3, bonding reliability such as bonding strength is improved, and variation in electrical characteristics of the joint structure for each semiconductor device 10 can be reduced.

### Third Embodiment: Semiconductor Device

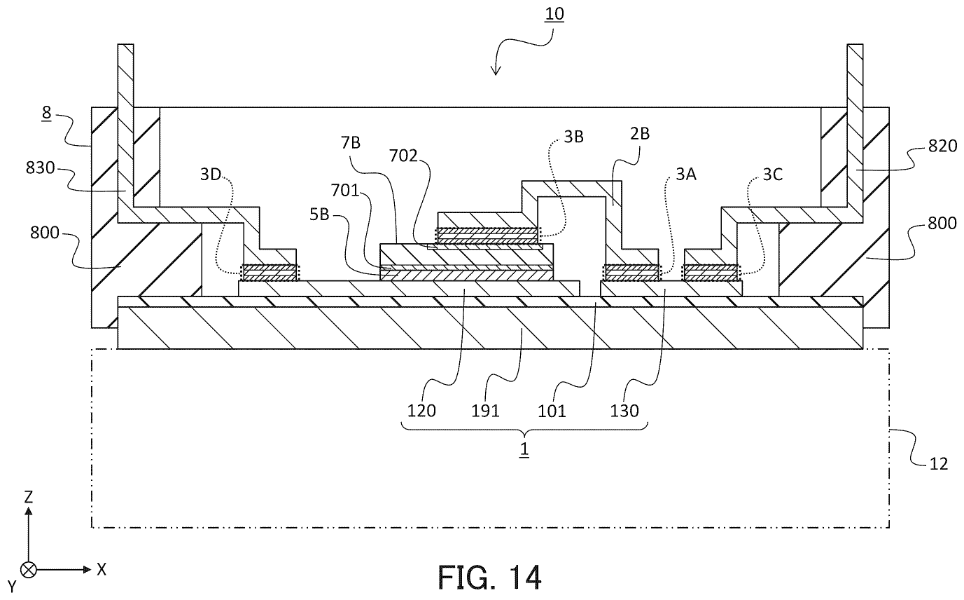

FIG. 14 is a cross-sectional view illustrating a configuration example of a semiconductor device according to a third embodiment. The cross section of FIG. 14 corresponds to the cross section of FIG. 12. In other words, the cross-sectional configuration of FIG. 14 may be a cross-sectional configuration at the position of the alternate long and short dash line D-D′ in the semiconductor device 10 of FIG. 11. In one side surface of the semiconductor device 10 illustrated in FIG. 14, it can be considered that the heat dissipation plate 4 arranged below the wiring board 1 in the semiconductor device 10 described in the second embodiment is omitted. The wiring board 1 in the semiconductor device 10 according to the third embodiment includes a metal base 191 that corresponds to the heat dissipation layer 190 of the second embodiment, an insulating layer 101 that is arranged on the top surface of the metal base 191, and a conductor pattern that is arranged on the insulating layer 101. The conductor pattern arranged on the insulating layer 101 includes the second conductor pattern 120 and the third conductor pattern 130 illustrated in FIG. 14 and the first conductor pattern 110 not illustrated in FIG. 14. The metal base 191 may be a metal plate such as copper or aluminum, and the insulating layer 101 may be a resin insulating material. The insulating layer 101 is formed, for example, by applying an uncured thermosetting resin to the top surface of the metal base 191 or arranging a semi-cured thermosetting resin sheet and then curing the thermosetting resin. The conductor pattern on the top surface of the insulating layer 101 is arranged, for example, on the top surface of the thermosetting resin when the thermosetting resin used for formation of the insulating layer 101 is in the semi-cured state, and is adhered to the insulating layer 101 in the step of curing the thermosetting resin in the semi-cured state. Note that, in the third embodiment, the laminate of the metal base 191, the insulating layer 101, and the conductor patterns 120 and 130, which is referred to as the wiring board 1, may be referred to as another term. For example, the wiring board 1 in the semiconductor device 10 in FIG. 14 can be referred to as a laminate in which the insulating layer 101 and the conductor patterns 120 and 130 are laminated on a top surface of the heat dissipation plate 4 on another side surface.

Similarly to the semiconductor device 10 of the second embodiment, the semiconductor device 10 of the third embodiment is manufactured by the manufacturing method including four steps of the first arrangement step, the first bonding step, the second arrangement step, and the second bonding step.

### Fourth Embodiment: Semiconductor Device

FIG. 15 is a cross-sectional view illustrating a configuration example of a semiconductor device according to a fourth embodiment. The cross-sectional configuration of FIG. 15 is intended to facilitate understanding of the featured configuration of the semiconductor device of the present embodiment and includes a portion that does not accurately represent the cross-sectional configuration in an actual semiconductor device. The semiconductor device 10 illustrated in FIG. 15 has a configuration in which a portion including the outer terminal portion (bonded portion) 814 of the first lead terminal 810 provided in the case 8 and a portion including the outer terminal portion (bonded portion) 824 of the second lead terminal 820 are bonded to each other by an insulating layer 860. The first lead terminal 810 and the second lead terminal 820 may be referred to as laminate terminals. The laminate terminal is manufactured by a known method, and the insulating material used as the insulating layer 860, the thickness of the insulating layer 860, and the like are selected according to electrical characteristics and the like required in the semiconductor device 10 to which the laminate terminal is applied.

In FIG. 15, an outer terminal portion 824 of the second lead terminal 820, the insulating layer 860, and an outer terminal portion 814 of the first lead terminal 810 are laminated in this order on a top surface 801 of the case body portion 800, but the arrangement of the outer terminal portion 824 of the second lead terminal 820 and the outer terminal portion 814 of the first lead terminal 810 may be reversed. The first lead terminal 810 and the second lead terminal 820 are not limited to terminals having specific functions in a circuit formed in the semiconductor device 10. The first lead terminal 810 and the second lead terminal 820 may be, for example, input terminals (P terminal and N terminal) in the inverter circuit 11 described above with reference to FIG. 13.

The inner terminal portion of the first lead terminal 810 is a portion extending to the upper portion of the wiring board 1 from the inner peripheral wall surface of the case body portion 800 and includes a bonded portion 811, a rising portion 812, and a routing portion 813. Similarly, the inner terminal portion of the second lead terminal 820 is a portion extending to the upper portion of the wiring board 1 from the inner peripheral wall surface of the case body portion 800 and includes a bonded portion 821, a rising portion 822, and a routing portion 823. The bonded portion 811 of the first lead terminal 810 is bonded to a conductor pattern 104 of the wiring board 1 in a laminated bonding material 3E, and the bonded portion 821 of the second lead terminal 820 is bonded to a conductor pattern 105 of the wiring board 1 by a laminated bonding material 3F. The laminated bonding material 3E and the laminated bonding material 3F can have any of the configurations described in the first embodiment. The semiconductor device 10 having the joint structure including the laminated bonding material 3E and the joint structure including the laminated bonding material 3F is manufactured by applying any one of the manufacturing methods described in the first embodiment to the second arrangement step and the second bonding step in the manufacturing method described in the second embodiment. Note that the routing portion 813 of the first lead terminal 810 illustrated as passing above the bonded portion 821 of the second lead terminal 820 in FIG. 15 passes through a position that does not hinder laser irradiation of the top surface of the bonded portion 821 of the second lead terminal 820 in an actual semiconductor device. That is, the first lead terminal 810 has a planar shape in which the routing portion 813 does not overlap the top surface of the bonded portion 821 of the second lead terminal 820 in the XY plane view.

In addition, in the semiconductor device 10 illustrated in FIG. 15, the outer terminal portion 814 of the first lead terminal 810 is bonded to a bus bar 15 by a laminated bonding material 3G. The bus bar 15 can be, for example, a conductor plate such as a terminal of an external power supply connected to an inverter circuit 11 of the semiconductor device 10 or a terminal of a smoothing capacitor connected in parallel to the inverter circuit 11. Furthermore, in the present specification, the conductor denoted by reference numeral 15 is referred to as a “bus bar 15” for convenience but is not limited to those referred to as a “bus bar”. Although not illustrated in FIG. 15, the outer terminal portion 824 of the second lead terminal 820 has a bonded portion that does not overlap the insulating layer 860 and the outer terminal portion 814 of the first lead terminal 810 in the XY plane view. The bonded portion of the outer terminal portion 824 of the second lead terminal 820 is bonded to a bus bar (not illustrated) by a laminated bonding material (not illustrated). A joint structure obtained by bonding the outer terminal portion 814 of the first lead terminal 810 and the bus bar 15 by the laminated bonding material 3G is also the same structure as the joint structure described in the first embodiment. Therefore, in the semiconductor device 10 according to the present embodiment, the first lead terminal 810 and the bus bar 15 can be bonded uniformly and firmly. In addition, it is possible to prevent heat from being directly and locally conducted from the bus bar 15 to the outer terminal portion 814 of the first lead terminal 810 when the top surface of the bus bar 15 is irradiated with laser. Therefore, for example, it is possible to prevent insulation deterioration due to thermal damage in the insulating layer 860 between the outer terminal portion 814 of the first lead terminal 810 and the outer terminal portion 824 of the second lead terminal 820. Further, by bonding the outer terminal portion 824 of the second lead terminal 820 and the bus bar (not illustrated) by the laminated bonding material, it is possible to prevent thermal damage from occurring in the case body portion 800 positioned below the outer terminal portion 824 of the second lead terminal 820. Although not illustrated in FIG. 15, in the semiconductor device 10 of the fourth embodiment, the third lead terminal 830 (see FIGS. 11 and 12) may also be bonded to the bus bar by a laminated bonding material.

Note that the first lead terminal 810 and the second lead terminal 820 in the semiconductor device 10 manufactured using the laminated bonding material 3 may have a planar shape in which the outer terminal portion 814 and the outer terminal portion 824 do not overlap each other or may not be a laminate terminal. In other words, each of the outer terminal portion 814 of the first lead terminal 810 and the outer terminal portion 824 of the second lead terminal 820 connected to the bus bar 15 may be formed by bending a portion extending upward from the top surface of the case body portion 800 in the semiconductor device 10 illustrated in FIG. 11 in a direction along the top surface of the case body portion 800. Also in this case, the outer terminal portion 814 and the outer terminal portion 824 are bonded to the bus bar by the laminated bonding material 3, so that bonding can be performed uniformly and firmly.

In addition, in this type of semiconductor device in the related art, for example, as a method of connecting the lead terminals 810, 820, and 830 provided in the case 8 to the bus bar, there is a method of forming a through hole in the outer terminal portion of the lead terminal and connecting the lead terminal and the bus bar with a bolt and a nut. However, in such a connection method, it is necessary to form a through hole in the lead terminal and the bus bar, and the shapes and structures of the lead terminal and the bus bar are restricted. In addition, since the connection between the outer terminal portion of the lead terminal and the bus bar by the bolt and the nut is made by contact, a current that can flow is restricted by the contact resistance, and it is difficult to increase the current of the semiconductor device 10. Furthermore, because the fastening is mechanical, it is likely that conduction failure occurs due to deformation during fastening or loosening due to vibration or the like after fastening. Meanwhile, in the semiconductor device 10 of the fourth embodiment, the flat top surfaces of the outer terminal portions of the lead terminals 810, 820, and 830 in which the through holes are not formed and the flat bottom surface of the bus bar 15 in which a through hole is not formed are bonded by the laminated bonding material 3 having the auxiliary conductor plate 300. Since this bonding is performed by the heat conduction type welding described in the first embodiment, deformation, damage, and other thermal damage can be prevented from occurring in the joint structure and the insulating material around the joint structure when the top surface of the bus bar 15 is irradiated with laser to bond the bus bar 15 and the outer terminal portion of the lead terminal. In addition, since the entire bonding interface is uniformly bonded by the laminated bonding material 3 having the auxiliary conductor plate 300, the restriction on the current that can flow between the bus bar 15 and the lead terminal is relaxed as compared with the case where the bus bar 15 and the lead terminal are in contact with each other, and the current of the semiconductor device 10 can be increased. Furthermore, since the entire bonding interface is uniformly bonded by the laminated bonding material 3, conduction failure is less likely to occur between the bus bar 15 and the lead terminal.

### (Supplement of Semiconductor Device)

Each of the second embodiment, the third embodiment, and the fourth embodiment described above is merely an example of an embodiment of a semiconductor device to which the joint structure described in the first embodiment is applied. The semiconductor device to which the joint structure described in the first embodiment is applied is not limited to the exemplified semiconductor device. For example, in the semiconductor device to which the joint structure is applied, as described above, the outer terminal portion 814 of the first lead terminal 810 and the outer terminal portion 824 of the second lead terminal 820 may be arranged along the top surface 801 of the case body portion 800 so as not to overlap each other in the XY plane view. The arrangement of the outer terminal portion 814 of the first lead terminal 810 and the outer terminal portion 824 of the second lead terminal 820 on the top surface 801 of the case body portion 800 is not limited to the arrangement in which the portions are arranged side by side in the Y-direction illustrated in FIG. 11, and may be an arrangement in which the portions are arranged side by side in the X-direction.

In the inverter circuit 11 of FIG. 13, the IGBT element 711 and the diode element 712 illustrated as being formed in one semiconductor element (for example, the semiconductor element 7A) may be formed in separate semiconductor elements. The switching element in the inverter circuit 11 is not limited to the IGBT element 711 and may be a power metal oxide semiconductor field effect transistor (MOSFET) element, a bipolar junction transistor (BJT) element, or the like. The diode element 712 of the inverter circuit 11 is not limited, for example, to the FWD element and may be a Schottky Barrier Diode (SBD) element, a Junction Barrier Schottky (JBS) diode element, a Merged PN Schottky (MPS) diode element, a PN diode element, or the like. For example, the semiconductor device may include only portions (upper arms) of the first lead terminal 810, the first semiconductor element 7A, the fourth lead terminal 840, and the third lead terminal 830 in the inverter circuit 11 illustrated in FIG. 13 or may include only portions (lower arms) of the third lead terminal 830, the second semiconductor element 7B and the fifth lead terminal 850, and the second lead terminal 820. In the semiconductor device, an inverter circuit having a circuit configuration different from that of the inverter circuit 11 illustrated in FIG. 13 may be formed, or a circuit different from the inverter circuit may be formed.

The semiconductor device may not include the case 8 in which the lead terminal is integrally formed. Specifically, the semiconductor device may be a resin-sealed semiconductor device sometimes referred to as a semiconductor package manufactured by mounting a semiconductor element on a lead frame and then sealing the semiconductor element or the like by transfer molding or the like.

Hereinafter, feature points in the above-described embodiments are summarized.

The joint structure according to the above-described embodiments includes a first conductor and a second conductor, and a laminated bonding material that is arranged between the first conductor and the second conductor and bonds the first conductor and the second conductor, in which the laminated bonding material includes a first bonding material layer bonded to the first conductor, a second bonding material layer bonded to the second conductor, and an auxiliary conductor plate arranged between the first bonding material layer and the second bonding material layer and having a higher melting point than the first bonding material layer and the second bonding material layer, and the second conductor has a laser irradiation mark on a back surface of a surface facing the auxiliary conductor plate.

In the joint structure according to the above embodiments, the first conductor is arranged on the insulating layer so that a back surface of a surface facing the auxiliary conductor plate faces the insulating layer.

In the joint structure according to the above embodiment, the ratio T2/T1 of the thickness T2 of a thinner bonding material layer of the first bonding material layer and the second bonding material layer to the thickness T1 of the auxiliary conductor plate is in a range of 0.0125≤T2/T1≤0.6.

In the joint structure according to the above embodiments, the first bonding material layer and the second bonding material layer are metal or an alloy having a melting point in a range of 100° C. to 300° C.

In the joint structure according to the above embodiments, the first bonding material layer and the second bonding material layer are tin or an alloy including tin.

In the joint structure according to the above embodiments, the first conductor and the second conductor are copper, an alloy including copper, nickel, or an alloy including nickel.

In the joint structure according to the above embodiments, the auxiliary conductor plate is any one of copper, an alloy including copper as a main component, nickel, an alloy including nickel as a main component, silver, an alloy including silver as a main component, aluminum, an alloy including aluminum as a main component, tungsten, and molybdenum.

A semiconductor device according to the above-described embodiments includes: a wiring board having an insulating layer and a conductor pattern arranged on a first surface of the insulating layer; a lead terminal bonded to the conductor pattern by a laminated bonding material; and a semiconductor element having an electrode electrically connected to the conductor pattern of the wiring board, in which the laminated bonding material includes: a first bonding material layer bonded to the conductor pattern; a second bonding material layer bonded to the lead terminal; and an auxiliary conductor plate arranged between the first bonding material layer and the second bonding material layer and having a higher melting point than the first bonding material layer and the second bonding material layer, and the lead terminal has a laser irradiation mark on a back surface of a surface facing the auxiliary conductor plate.

A semiconductor device according to the above-described embodiments includes: a semiconductor element; and a lead terminal bonded to an electrode of the semiconductor element by a laminated bonding material, in which the laminated bonding material includes: a first bonding material layer bonded to the electrode of the semiconductor element; a second bonding material layer bonded to the lead terminal; and an auxiliary conductor plate arranged between the first bonding material layer and the second bonding material layer and having a higher melting point than the first bonding material layer and the second bonding material layer, and the lead terminal has a laser irradiation mark on a back surface of a surface facing the auxiliary conductor plate.

A semiconductor device according to the above-described embodiments includes: a semiconductor element sealed by an insulating member; a lead terminal having an outer terminal portion electrically connected to an electrode of the semiconductor element and exposed from the insulating member; and a conductor plate bonded to the outer terminal portion of the lead terminal by a laminated bonding material, in which the laminated bonding material includes: a first bonding material layer bonded to the lead terminal; a second bonding material layer bonded to the conductor plate; and an auxiliary conductor plate arranged between the first bonding material layer and the second bonding material layer and having a melting point higher than the first bonding material layer and the second bonding material layer, and the conductor plate has a laser irradiation mark on a back surface of a surface facing the auxiliary conductor plate.

In the semiconductor device according to the above embodiments, the lead terminal includes a first lead terminal and a second lead terminal, and the first lead terminal and the second lead terminal are laminate terminals in which a portion of the first lead terminal and a portion of the second lead terminal are laminated to each other via an insulating layer.

A manufacturing method of a joint structure according to the above-described embodiments includes: an arrangement step of arranging a first bonding material layer, an auxiliary conductor plate, a second bonding material layer, and a second conductor so that the first bonding material layer, the auxiliary conductor plate, the second bonding material layer, and the second conductor are laminated in this order on the first conductor; and a bonding step of irradiating a back surface of a surface facing the auxiliary conductor plate in the second conductor with laser, heating the second bonding material layer and the first bonding material layer, and bonding the first conductor and the second conductor, in which the auxiliary conductor plate is formed of a conductive material having a higher melting point than the first bonding material layer and the second bonding material layer.

In the manufacturing method of a joint structure according to the above embodiments, a wavelength of the laser is in a range of 500 nm to 550 nm.

In the manufacturing method of a joint structure according to the above embodiment, in the arrangement step, a laminated bonding material obtained by integrating the first bonding material layer, the auxiliary conductor plate, and the second bonding material layer is arranged on the first conductor.

In the manufacturing method of a joint structure according to the above embodiments, the laminated bonding material is obtained by laminating and integrating the first bonding material layer, the auxiliary conductor plate, and the second bonding material layer.

In the manufacturing method of a joint structure according to the above embodiments, the laminated bonding material is obtained by depositing the first bonding material layer on a bottom surface of the auxiliary conductor plate, and depositing the second bonding material layer on a top surface of the auxiliary conductor plate.

In the manufacturing method of a joint structure according to the above embodiments, with respect to the first bonding material layer and the second bonding material layer arranged in the arrangement step, the first bonding material layer includes a bonding material layer arranged or deposited on a top surface of the first conductor and a bonding material layer arranged or deposited on a bottom surface of the auxiliary conductor plate, or the second bonding material layer includes a bonding material layer arranged or deposited on a top surface of the auxiliary conductor plate and a bonding material layer arranged or deposited on a bottom surface of the second conductor.

In the manufacturing method of a joint structure according to the above embodiments, in the bonding step, the laser is applied under an irradiation condition in which the first conductor and the second conductor are bonded by heat conduction type welding of melting the second bonding material layer and the first bonding material layer and forming an alloy at an interface between the second conductor and the second bonding material layer and an interface layer between the first conductor and the first bonding material layer.

In the manufacturing method of a joint structure according to the above embodiments, the first bonding material layer and the second bonding material layer are tin or an alloy including tin.

In the manufacturing method of a joint structure according to the above embodiments, the auxiliary conductor plate is any one of copper, an alloy including copper as a main component, nickel, an alloy including nickel as a main component, silver, an alloy including silver as a main component, aluminum, an alloy including aluminum as a main component, tungsten, and molybdenum.

The manufacturing method of a semiconductor device according to the above-described embodiments includes a first arrangement step of arranging a semiconductor element on a wiring board having an insulating layer and a conductor pattern arranged on a first surface of the insulating layer, a second arrangement step of arranging a first bonding material layer, an auxiliary conductor plate, a second bonding material layer, and a lead terminal on the conductor pattern of the wiring board so that the first bonding material layer, the auxiliary conductor plate, the second bonding material layer, and the lead terminal are laminated in this order; and a bonding step of irradiating a back surface of a surface facing the auxiliary conductor plate in the lead terminal with laser, heating the second bonding material layer and the first bonding material layer, and bonding the conductor pattern of the wiring board and the lead terminal, in which the auxiliary conductor plate is formed of a conductive material having a higher melting point than the first bonding material layer and the second bonding material layer.

The manufacturing method of a semiconductor device according to the above-described embodiments includes a first arrangement step of arranging a semiconductor element on a wiring board having an insulating layer and a conductor pattern arranged on a first surface of the insulating layer, a second arrangement step of arranging a first bonding material layer, an auxiliary conductor plate, a second bonding material layer, and a lead terminal on an electrode of the semiconductor element so that the first bonding material layer, the auxiliary conductor plate, the second bonding material layer, and the lead terminal are laminated in this order; and a bonding step of irradiating a back surface of a surface facing the auxiliary conductor plate in the lead terminal with laser, heating the second bonding material layer and the first bonding material layer, and bonding the electrode of the semiconductor element and the lead terminal, in which the auxiliary conductor plate is formed of a conductive material having a higher melting point than the first bonding material layer and the second bonding material layer.

A manufacturing method of a semiconductor device according to the above-described embodiments includes: an arrangement step of arranging a first bonding material layer, an auxiliary conductor plate, a second bonding material layer, and a conductor plate so that the first bonding material layer, the auxiliary conductor plate, the second bonding material layer, and the conductor plate are laminated in this order on a first surface of the outer terminal portion in a lead terminal having an outer terminal portion exposed from the insulating member electrically connected to an electrode of a semiconductor element seal with an insulating member; and a bonding step of irradiating a back surface of a surface facing the auxiliary conductor plate in the conductor plate with laser, heating the second bonding material layer and the first bonding material layer, and bonding the lead terminal and the conductor plate, in which the auxiliary conductor plate is formed of a conductive material having a higher melting point than the first bonding material layer and the second bonding material layer.

Note that the present invention is not limited to the above-described embodiments, and various changes, substitutions, and modifications may be made without departing from the spirit of the technical idea. Further, when the technical idea may be implemented in another method by the progress of the technology or another derived technology, the technical idea may be carried out by using the method thereof. Therefore, the claims cover all implementations that may be included within the scope of the technical idea.

As described above, the present invention has an effect of preventing surrounding members having low heat resistance from deteriorating due to heat when the bonding material between the first conductor and the second conductor is melted and bonded and is particularly useful by being applied to a semiconductor device for industrial or vehicle used as a power converter.

What is claimed is:

1. A joint structure, comprising:
a first conductor and a second conductor; and
a laminated bonding material that is arranged between the first conductor and the second conductor to bond the first conductor to the second conductor;
wherein the laminated bonding material includes:
a first bonding material layer bonded to the first conductor;
a second bonding material layer bonded to the second conductor; and
an auxiliary conductor plate arranged between the first bonding material layer and the second bonding material layer, the auxiliary conductor plate having a melting point higher than melting points of the first bonding material layer and the second bonding material layer; and
wherein the second conductor has a laser irradiation mark on a back surface thereof, the back surface being opposite to a front surface of the second conductor that faces the laminated bonding material.

2. The joint structure according to claim 1, further comprising an insulating layer on which the first conductor is arranged, wherein
a back surface of the first conductor faces the insulating layer, and a front surface of the first conductor faces the laminated bonding material.

3. The joint structure according to claim 1, wherein:
a thickness of the auxiliary conductor plate is denoted as T1;
a thickness of a thinner one among the first bonding material layer and the second bonding material layer is denoted as T2; and
a ratio T2/T1 is in a range of 0.0125≤T2/T1≤0.6.

4. The joint structure according to claim 1, wherein the first bonding material layer and the second bonding material layer each are made of a metal or an alloy having a melting point in a range of 100° C. to 300° C.

5. The joint structure according to claim 4, wherein the first bonding material layer and the second bonding material layer each are made of tin or an alloy containing tin.

6. The joint structure according to claim 5, wherein the first conductor and the second conductor are made of copper or an alloy containing copper, or of nickel or an alloy containing nickel.

7. The joint structure according to claim 1, wherein the auxiliary conductor plate is made of any one of: copper; an alloy containing copper as a main component; nickel; an alloy containing nickel as a main component; silver; an alloy containing silver as a main component; aluminum; an alloy containing aluminum as a main component; tungsten; or molybdenum.

8. A semiconductor device, comprising:
a wiring board having an insulating layer and a conductor pattern arranged on a front surface of the insulating layer;
a lead terminal;
a laminated bonding material that bonds the conductor pattern to the lead terminal; and
a semiconductor element having an electrode electrically connected to the conductor pattern of the wiring board;
wherein the laminated bonding material includes:
a first bonding material layer bonded to the conductor pattern;
a second bonding material layer bonded to the lead terminal; and
an auxiliary conductor plate arranged between the first bonding material layer and the second bonding material layer, the auxiliary conductor plate having a melting point higher than melting points of the first bonding material layer and the second bonding material layer; and
wherein the lead terminal has a laser irradiation mark on a back surface thereof, a front surface of the lead terminal opposite the back surface facing the auxiliary conductor plate.

9. A manufacturing method of a joint structure, comprising:
arranging a first bonding material layer, an auxiliary conductor plate, a second bonding material layer, and a second conductor such that the first bonding material layer, the auxiliary conductor plate, the second bonding material layer, and the second conductor are laminated in this order on the first conductor in an arrangement step; and
irradiating a back surface of the second conductor that is opposite a front surface of the second conductor facing the auxiliary conductor plate, with laser, thereby heating the second bonding material layer and the first bonding material layer, to bond the first conductor to the second conductor in a bonding step;
wherein the auxiliary conductor plate is made of a conductive material having a melting point higher than melting points of the first bonding material layer and the second bonding material layer.

10. The manufacturing method of a joint structure according to claim 9, wherein a wavelength of the laser is in a range of 500 nm to 550 nm.

11. The manufacturing method of a joint structure according to claim 9, wherein, in the arrangement step, a laminated bonding material is arranged on the first conductor, by integrating the first bonding material layer, the auxiliary conductor plate, and the second bonding material layer.

12. The manufacturing method of a joint structure according to claim 11, wherein the laminated bonding material is obtained by laminating and integrating the first bonding material layer, the auxiliary conductor plate, and the second bonding material layer.

13. The manufacturing method of a joint structure according to claim 11, wherein the laminated bonding material is obtained by depositing the first bonding material layer on a back surface of the auxiliary conductor plate, and depositing the second bonding material layer on a front surface of the auxiliary conductor plate.

14. The manufacturing method of a joint structure according to claim 9, wherein:
the first bonding material layer includes one bonding material layer arranged or deposited on a front surface of the first conductor, and another bonding material layer arranged or deposited on a back surface of the auxiliary conductor plate; or
the second bonding material layer includes one bonding material layer arranged or deposited on a front surface of the auxiliary conductor plate, and another bonding material layer arranged or deposited on a back surface of the second conductor.

15. The manufacturing method of a joint structure according to claim 9, wherein, in the bonding step, the laser is applied under an irradiation condition in which the first conductor and the second conductor are bonded by heat conduction welding, the heat conduction welding including:
melting the second bonding material layer and the first bonding material layer; and
forming an alloy at an interface between the second conductor and the second bonding material layer and an interface layer between the first conductor and the first bonding material layer.

16. The manufacturing method of a joint structure according to claim 9, wherein the first bonding material layer and the second bonding material layer are made of tin or an alloy containing tin.

17. The manufacturing method of a joint structure according to claim 9, wherein the auxiliary conductor plate is made of any one of: copper; an alloy containing copper as a main component; nickel; an alloy containing nickel as a main component; silver; an alloy containing silver as a main component; aluminum; an alloy containing aluminum as a main component; tungsten; or molybdenum.
